(19) United States
(12) Patent Application Publication
(10) Pub. No.: US 2024/0330534 A1
(43) Pub. Date: Oct. 3, 2024

(54) APPARATUS AND METHODS FOR BATTERY MODEL GENERATION

(71) Applicant: BETA AIR, LLC, SOUTH BURLINGTON, VT (US)

(72) Inventor: Steven J. Foland, SOUTH BURLINGTON, VT (US)

(73) Assignee: BETA AIR, LLC, SOUTH BURLINGTON, VT (US)

(21) Appl. No.: 18/128,665

(22) Filed: Mar. 30, 2023

(51) Int. Cl. G06F 30/20

(52) U.S. Cl. CPC G06F 30/20

(57) ABSTRACT

An apparatus for generating a battery model is provided. Battery model may be generated using measurement data and/or fleet data related to one or more battery packs of one or more electric aircraft. Battery model may then be used to determine performance analytics of the one or more battery packs for reference by a user to improve power source usage and operation.

### FIELD OF THE INVENTION

The present invention generally relates to the field of electric aircrafts. In particular, the present invention is directed to apparatus and methods for battery model generation using offloaded data.

### BACKGROUND

The burgeoning of electric vertical take-off and landing (eVTOL) aircraft technologies promises an unprecedented forward leap in energy efficiency, cost savings, and the potential of future autonomous and unmanned aircraft. However, the technology of eVTOL aircraft is still lacking in crucial areas of energy source management.

### SUMMARY OF THE DISCLOSURE

In an aspect, an apparatus for generating a battery pack model is described. The apparatus includes a processor communicatively connected to one or more electric aircraft battery packs and a memory communicatively connected to the processor, the memory containing instructions configuring the processor to retrieve measurement data associated with the one or more battery packs of an electric aircraft, provide fleet data as a function of the measurement data, generate a battery model as a function of the measurement data, and determine performance analytics using the battery model.

In another aspect, a method for generating a battery pack model is described. The method includes receiving, by a controller communicatively connected to a battery pack of an electric aircraft, measurement data associated with a battery pack of an electric aircraft, transmitting, by the controller, measurement data to a database communicatively connected to the controller using a communication connection; and generating, by a remote computing device communicatively connected to the controller and the database, a digital model of the battery pack as a function of the measurement data, wherein the digital model comprises one or more performance analytics.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 a block diagram of an exemplary embodiment of a system for battery model generation in accordance with one or more aspects of the present disclosure;

FIG. 2 is a block diagram of an exemplary embodiment of a battery pack in one or more aspects of the present disclosure;

FIG. 3 is an illustration of an exemplary embodiment of a sensor suite in partial cut-off view in one or more aspects of the present disclosure;

FIG. 4 is a block diagram of an exemplary embodiment of a module monitor unit in one or more aspect of the present disclosure;

FIG. 5 is a block diagram of another exemplary embodiment a pack monitor unit in one or more aspect of the present disclosure;

FIGS. 6A and 6B are illustrations of exemplary embodiments of battery pack configured for use in an electric aircraft in isometric view in accordance with one or more aspects of the present disclosure;

FIG. 7 is a flow chart of an exemplary embodiment of a method of battery pack management in one or more aspects of the present disclosure;

FIG. 8 is an illustration of an embodiment of an electric aircraft in one or more aspect of the present disclosure;

FIG. 9 is a block diagram of a flight controller of an electric aircraft in one or more aspect of the present disclosure;

FIG. 10 is a block diagram of an exemplary embodiment of machine-learning module in one or more aspect of the present disclosure; and

FIG. 11 is a block diagram of an exemplary embodiment of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

Battery management apparatus and related techniques are provided to improve the monitoring and management of an electric aircraft energy source. More specifically, a processor communicatively connected to a battery management component of an energy source, such as a battery pack, may collect and compile measurement data associated with one or more battery packs of one or more electric aircraft to create fleet data; a battery model may then be generated as a function of fleet data and battery model may be used to determine performance analytics 156, such as performance analytics, of a plurality of battery packs of a fleet of aircraft. Measurement data may be collected during operation of electric aircraft, such as taxing or flight. Measurement data may then be transferred to one or more nodes of a network, such as one or more remote computing devices. Measurement data may be offloaded to the one or more nodes during, for example, charging of battery pack. For instance, and without limitation, measurement data may be transmitted from processor to a remote computing device using, for example and without limitation, a wireless transceiver or a wired connection, such as a connector of an electric charger. Once measurement data has been offloaded, a battery model of battery pack may be generated by the one or more computing devices. The digital model may include information related to the battery pack, such as state of charge (SoC), depth of discharge (DoD), cathode health, anode health, electrolyte depletion levels, and the like.

In the following description, for the purposes of explanation, numerous specific details are set forth in order to provide a thorough understanding of the present invention. It will be apparent, however, that the present invention may be practiced without these specific details. As used herein, the word “exemplary” or “illustrative” means “serving as an example, instance, or illustration.” Any implementation described herein as “exemplary” or “illustrative” is not necessarily to be construed as preferred or advantageous over other implementations. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply embodiments of the inventive concepts defined in the appended claims. Hence, specific dimensions and other physical characteristics relating to the embodiments disclosed herein are not to be considered as limiting, unless the claims expressly state otherwise.

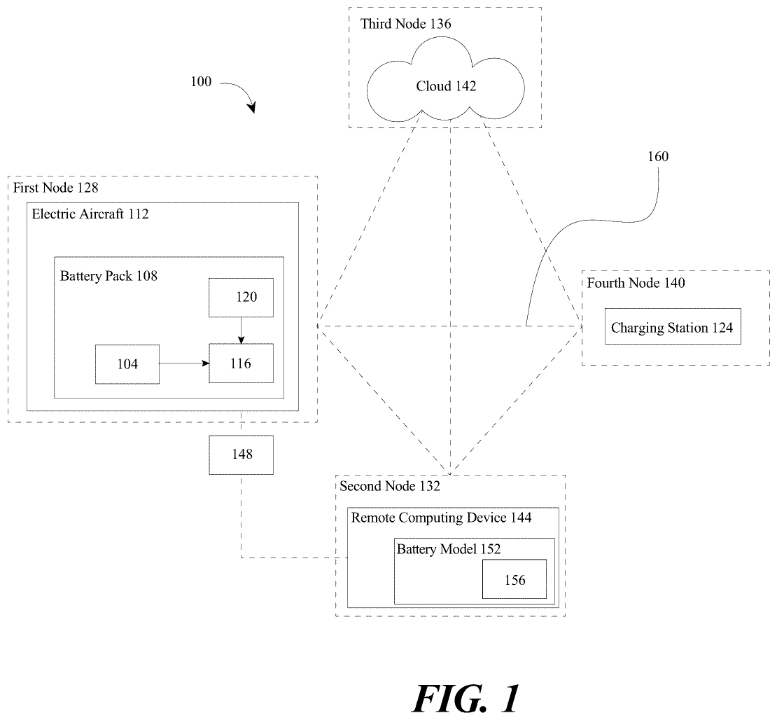

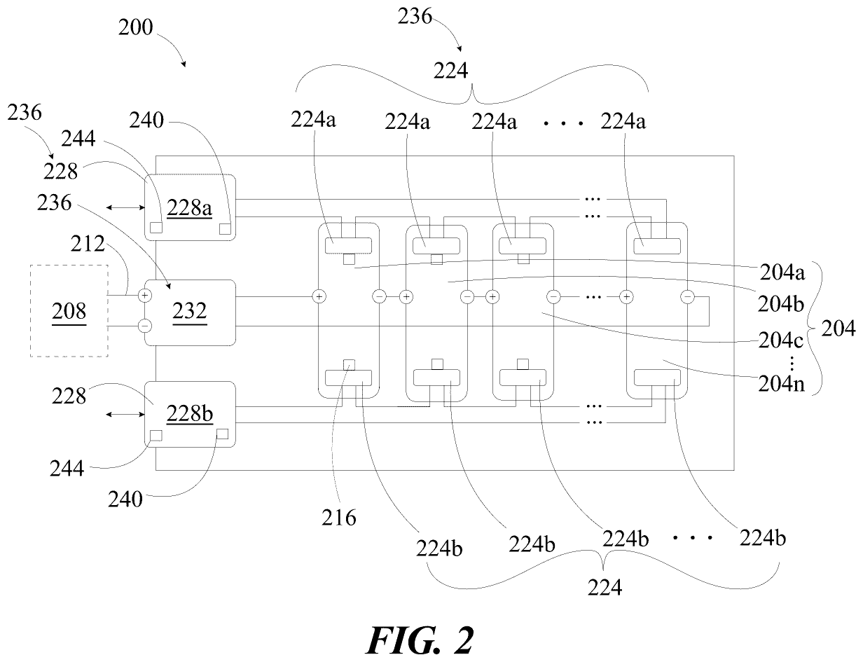

Referring now to FIG. 1, an exemplary embodiment of apparatus 100 is presented in accordance with one or more embodiments of the present disclosure. In one or more embodiments, apparatus 100 includes a computing device 104. In some embodiments, computing device 104 may be a separate, independent device. In other embodiments, computing device 104 may include a computing device of a charging station. In other embodiments, computing device 104 may include a computing device of a remote computing device. Computing device 104 may include a processor and a memory. Processor may be communicatively communicated to a power source, such as battery pack 108, of an electric aircraft 112. Memory may be communicatively connected to processor and may provide instructions configuring processor to execute any steps or methods described in this disclosure. In various embodiments, computing device 104 may include a first computing device. In other embodiments, computing device 104 may include a flight controller, as described further in this disclosure. In other embodiments, computing device 104 may include a battery management component or battery management system (BMS) of battery pack 108. Computing device 104 may include a computing device configured to monitor one or more characteristics of a power source, such as a battery pack 108 of an electric aircraft 112. In some embodiments, computing device 104 may include or be incorporated into a computing device attached to battery pack 108. In other embodiments, computing device 104 may be remote from battery pack 108. In other embodiments, electric aircraft 112 may include computing device 104. As previously mentioned, computing device 104 may include or be a component of a computing device, such as a first computing device. Computing device may include any computing device as described in this disclosure, including without limitation a microcontroller, microprocessor, digital signal processor (DSP), a flight controller, and/or system on a chip (SoC) as described in this disclosure. Computing device may include, be included in, and/or communicate with a mobile device such as a mobile telephone or smartphone. In several embodiments, computing device 104 may include a battery management component of battery pack 108, such as battery management component of FIG. 2. A “battery management component,” for the purposes of this disclosure, is a device or component configured to monitor and regulate one or more parameters or characteristics of a battery pack. For instance, and without limitation, battery management component (also referred to as a “battery management system” or “BMS”) may be attached to battery pack 108 and may monitor characteristics of battery pack. Battery management component may be communicatively connected to sensors of apparatus 100 or include sensors of apparatus 100. In other embodiments, computing device 104 may include a sensor, such as an individual sensor or a sensor suite, as discussed further below in this disclosure.

Still referring to FIG. 1, computing device 104 may include a single computing device operating independently, or may include two or more computing device operating in concert, in parallel, sequentially or the like; two or more computing devices may be included together in a single computing device or in two or more computing devices. Computing device may interface or communicate with one or more additional devices as described below in further detail via a network interface device. Network interface device may be utilized for connecting computing device to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Computing device may include but is not limited to, for example, a computing device or cluster of computing devices in a first location and a remote computing device or cluster of computing devices in a second location. Computing device may include one or more computing devices dedicated to data storage, security, distribution of traffic for load balancing, and the like. Computing device may distribute one or more computing tasks as described below across a plurality of computing devices of computing device, which may operate in parallel, in series, redundantly, or in any other manner used for distribution of tasks or memory between computing devices. Computing device may be implemented using a “shared nothing” architecture in which data is cached at the worker, in an embodiment, this may enable scalability of charging station and/or computing device.

With continued reference to FIG. 1, computing device 104 may be designed and/or configured to perform any method, method step, or sequence of method steps in any embodiment described in this disclosure, in any order and with any degree of repetition. For instance,[computing device may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Computing device 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

Still referring to FIG. 1, in one or more embodiments, computing device 104 may be configured to retrieve measurement data 116 associated with battery pack 108 of electric aircraft 112. A “measurement datum,” for the purposes of this disclosure, refers to a datum associated with physical or electrical characteristics or parameters of battery pack 108. For instance, and without measurement data may include parameters such as nominal voltage, standard discharge capacity (per the manufacturer or from historical data and performance analytics 156) standard discharge current, standard charge current, rated discharge capacity, rated discharge current, rated charge current, internal impedance temperature, upper and lower cutoff voltages, standard operating temperatures (e.g., ambient or internal/surface of battery pack), measurement data 116 may include a state of charge (SoC) of battery pack 108, a voltage rating of battery pack 108, a current of battery pack 108, a depth of discharge (DoD) of battery pack 108, a temperature of battery pack 108, a failure detection of battery pack 108, capacitance, impedance, resistance, plating (e.g., lithium plating of components of battery pack), environmental pressure, pressure of a component of battery pack 108, degradation of battery pack 108, moisture levels, or the like. “Depth of discharge”, as referred herein for the purpose of this disclosure, refers to the percentage of the battery that has being discharged, or the percentage that is not useful energy, that is determined as a function of the useful energy remaining datum. In a nonlimiting example, the computing device 104 may display to a user the remaining useful energy and a percentage of the battery that is devoid of energy or has energy that cannot be used. Any computing device capable of displaying information to the user may be used to display the useful energy remaining data. The plurality of measured aircraft operation datum may include a record of potential maintenance and repair schedules corresponding to an electric aircraft. In one or more embodiments, measurement data 116 may be inputted by a user, such as an operator or pilot. In some embodiments, a user may input measurement data into computing device using, for example and without limitation, a graphical user interface, which is described further below in this disclosure. In other embodiments, user may input measurement data into cloud database so that computing device may retrieve measurement data from cloud database.

Still referring to FIG. 1, in one or more embodiments, measurement data 116 may be generated by a sensor 120. Computing device 104 may be communicatively connected to a sensor 120 and/or sensor suite. Sensor 120 may include one or more sensors, such as a sensor suite, sensor array, or independent sensors, that may be attached to electric aircraft 112 and/or battery pack 108. Sensor 120 may include, but is not limited to, a multimeter, voltmeter, valve electrometer, solid-state electrometer, and the like. As used in this disclosure, a “sensor” is a device that is configured to detect an input and/or a phenomenon, generate data related to the input and/or phenomenon, and transmit the data related to the detection. For instance, and without limitation, sensor 120 may detect a characteristic of battery pack 108, such as temperature, SoC, DoD, moisture levels, component health, and the like. Sensor 120 may be integrated and/or connected to battery pack 108, a portion thereof, or any subcomponent thereof. Sensor 120 may include circuitry or electronic components configured to digitize, transform, or otherwise manipulate electrical signals. Electrical signals may include analog signals, digital signals, periodic or aperiodic signal, step signals, unit impulse signal, unit ramp signal, unit parabolic signal, signum function, exponential signal, rectangular signal, triangular signal, sinusoidal signal, sinc function, or pulse width modulated signal. The plurality of datum captured by sensor 120 may include circuitry, computing devices, electronic components or a combination thereof that translates into at least an electronic signal configured to be transmitted to another electronic component.

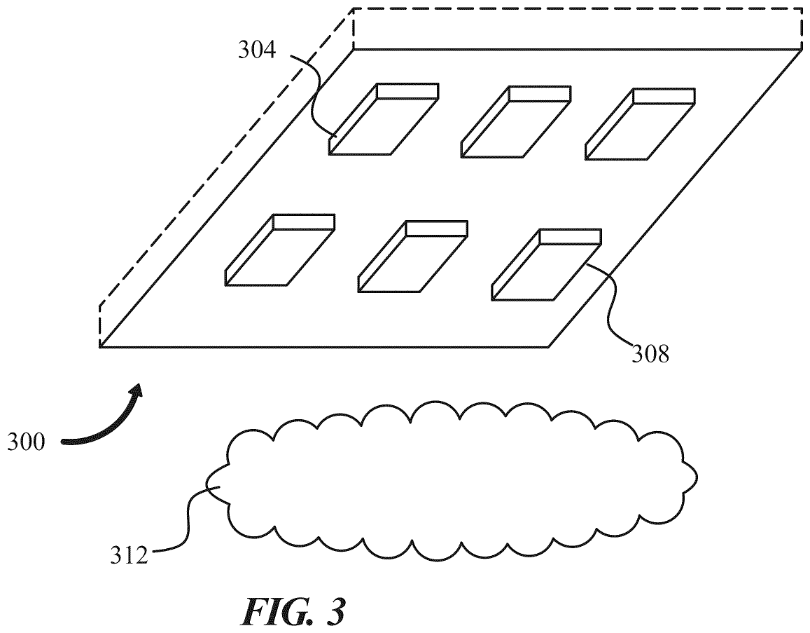

With continued reference to FIG. 1, sensor 120 may include a plurality of sensors in the form of individual sensors or a sensor suite working in tandem or individually, as discussed further in FIG. 3. Independent sensors may include separate sensors measuring physical or electrical quantities that may be powered by and/or in communication with circuits independently, where each may signal sensor output to a control circuit, such as computing device 104. In an embodiment, use of a plurality of independent sensors may result in redundancy configured to employ more than one sensor that measures the same phenomenon, those sensors being of the same type, a combination of, or another type of sensor not disclosed, so that in the event one sensor fails, the ability to detect phenomenon is maintained and in a non-limiting example, a user alter aircraft usage pursuant to sensor readings. Sensor may be configured to detect pilot input from at least pilot control so that controller may make correlations between pilot input and battery pack function. At least pilot control may include a throttle lever, inceptor stick, collective pitch control, steering wheel, brake pedals, pedal controls, toggles, joystick. One of ordinary skill in the art, upon reading the entirety of this disclosure would appreciate the variety of Collective pitch control may be consistent with disclosure of collective pitch control in U.S. patent application Ser. No. 16/929,206 and titled “HOVER AND THRUST CONTROL ASSEMBLY FOR DUAL-MODE AIRCRAFT”, which is incorporated herein by reference in its entirety.

With continued reference to FIG. 1, sensor 120 may include a motion sensor. A “motion sensor,” for the purposes of this disclosure is a device or component configured to detect physical movement of an object or grouping of objects. One of ordinary skill in the art would appreciate, after reviewing the entirety of this disclosure, that motion may include a plurality of types including but not limited to: spinning, rotating, oscillating, gyrating, jumping, sliding, reciprocating, or the like. Sensor 120 may include, but not limited to, torque sensor, gyroscope, accelerometer, magnetometer, inertial measurement unit (IMU), pressure sensor, force sensor, proximity sensor, displacement sensor, vibration sensor, LIDAR sensor, and the like. microelectromechanical machine, at least a scanner and/or optic, a photodetector, a specialized GPS receiver, and the like. In a non-limiting embodiment, sensor 120 including a LIDAR system may targe an object with a laser and measure the time for at least a reflected light to return to the LIDAR system. LIDAR may also be used to make digital 4-D representations of areas on the earth's surface and ocean bottom, due to differences in laser return times, and by varying laser wavelengths. In a non-limiting embodiment, the LIDAR system may include a topographic LIDAR and a bathymetric LIDAR, wherein the topographic LIDAR that may use near-infrared laser to map a plot of a land or surface representing a potential landing zone or potential flight path while the bathymetric LIDAR may use water-penetrating green light to measure seafloor and various water level elevations within and/or surrounding the potential landing zone. In a non-limiting embodiment, electric aircraft may use at least a LIDAR system as a means of obstacle detection and avoidance to navigate safely through environments to reach a potential landing zone. Sensor 120 may include a sensor suite which may include a plurality of sensors that may detect similar or unique phenomena. For example, in a non-limiting embodiment, sensor suite may include a plurality of accelerometers, a mixture of accelerometers and gyroscopes, or a mixture of an accelerometer, gyroscope, and torque sensor.

For instance, sensor 120 may detect a condition characteristic of battery pack to generate measurement data 116. A “condition characteristic”, for the purposes of this disclosure, is a physical or electrical feature of a battery pack. For example, and without limitation, a sensor may transduce a detected power phenomenon and/or characteristic, such as, and without limitation, temperature, voltage, current, and the like, into a sensed signal. In one or more embodiments, and without limitation, sensor may include a plurality of sensors. In one or more embodiments, and without limitation, sensor may include one or more temperature sensors, voltmeters, current sensors, hydrometers, infrared sensors, photoelectric sensors, ionization smoke sensors, motion sensors, pressure sensors, radiation sensors, level sensors, imaging devices, moisture sensors, gas and chemical sensors, flame sensors, electrical sensors, imaging sensors, force sensors, Hall sensors, state of charger (SOC) sensors, and the like. For example, and without limitation, SOC sensor may be communicatively connected to computing device 104 and battery pack 108, and SOC sensor may be configured to detect measurement data associated with an energy level of battery pack 108. In one or more embodiments, sensor may be a contact or a non-contact sensor. For instance, and without limitation, sensor may be connected to electric aircraft 112, battery pack 108, and/or computing device 104. In other instances, sensor may be remote to electric aircraft 112, battery pack 108, and/or computing device 104. Signals may include electrical, electromagnetic, visual, audio, radio waves, or another undisclosed signal type alone or in combination.

Still referring to FIG. 1, sensor 120 may include a plurality of independent sensors, where any number of the described sensors may be used to detect any number of physical or electrical quantities associated with communication of charging connection. Independent sensors may include separate sensors measuring physical or electrical quantities that may be powered by and/or in communication with circuits independently, where each may signal sensor output to a control circuit such as a user graphical interface. In an embodiment, use of a plurality of independent sensors may result in redundancy configured to employ more than one sensor that measures the same phenomenon, those sensors being of the same type, a combination of, or another type of sensor not disclosed, so that in the event one sensor fails, the ability of sensor to detect phenomenon may be maintained. In one or more embodiments, sensor 120 may include various types of sensors, as discussed further in FIG. 3. For instance, and without limitation, sensor 120 may include electrical sensors. Electrical sensors may be configured to measure voltage across a component, electrical current through a component, and resistance of a component. In one or more embodiments, sensor may include thermocouples, thermistors, thermometers, infrared sensors, resistance temperature sensors (RTDs), semiconductor based integrated circuits (ICs), a combination thereof, or another undisclosed sensor type, alone or in combination. Temperature, for the purposes of this disclosure, and as would be appreciated by someone of ordinary skill in the art, is a measure of the heat energy of a system. Temperature, as measured by any number or combinations of sensors present within sensor, may be measured in Fahrenheit (° F.), Celsius (° C.), Kelvin (° K), or another scale alone or in combination. The temperature measured by sensors may comprise electrical signals, which are transmitted to their appropriate destination wireless or through a wired connection.

Still referring to FIG. 1, retrieving measurement data associated with battery pack 108 may include computing device 104 retrieving measurement data 116 from battery pack 108 directly, such as by using a battery management component, or indirectly, such as by using sensor 120. Computing device 104 may be connected to battery pack 108 to directly retrieve measurement data from battery pack 108. For the purposes of this disclosure, a “battery pack” is a power source that is configured to store and/or transmit electrical energy. Battery pack may store electrical energy in the form of a plurality of battery modules, which themselves are composed of a plurality of electrochemical cells. These cells may utilize electrochemical cells, galvanic cells, electrolytic cells, fuel cells, flow cells, and/or voltaic cells. For the purposes of this disclosure, a “battery module” is a battery pack component that includes a cluster of battery cells. For the purposes of this disclosure, a “battery cell” is a component of a battery module that generates electric power. In various embodiments, a batter cell may include an electrochemical cell. In general, an electrochemical cell is a device capable of generating electrical energy from chemical reactions or using electrical energy to cause chemical reactions, this disclosure will focus on the former. Voltaic or galvanic cells are electrochemical cells that generate electric current from chemical reactions, while electrolytic cells generate chemical reactions via electrolysis. In general, the term “battery” is used as a collection of cells connected in series or parallel to each other. A battery cell may, when used in conjunction with other cells, may be electrically connected in series, in parallel or a combination of series and parallel. Series connection comprises wiring a first terminal of a first cell to a second terminal of a second cell and further configured to comprise a single conductive path for electricity to flow while maintaining the same current (measured in Amperes) through any component in the circuit. Battery pack 108 may include one or more battery modules, as shown in FIG. 2. Battery pack 108 may include a housing configured to receive and/or at least partially encase one or more battery modules. A “housing”, for the purposes of this disclosure, is a structure that at least partially contains components of a battery pack. For instance, and without limitation, battery modules may be contained within an interior cavity of housing. Each battery module of the plurality of battery modules may include any battery module as described in further detail in the entirety of this disclosure. As an exemplary, nonlimiting embodiment, seven battery modules may create battery pack 108. However, a person of ordinary skill in the art would understand that any number of battery modules may be housed within battery pack 100. In an embodiment, each battery module of plurality of battery modules may include one or more battery cells. Each battery module is configured to house and/or encase one or more battery cells. Each battery cell of the plurality of battery cells may include any battery cell as described in further detail in the entirety of this disclosure. For example, and without limitation, battery cell may include a cylindrical battery cell, rectangular battery cell, a pouch cell, and the like. One or more battery cells may be disposed at least partially within each battery module, wherein each battery cell is disposed in any configuration without limitation. For example, and without limitation, battery cells may be stacked, staggered, randomly arranged, any combination thereof, and the like. As an exemplary, nonlimiting example, 240 battery cells may be housed within each battery module. However, a person of ordinary skill in the art would understand that any number of battery cells 108A-N may be housed within each battery module of battery pack 108. Additional disclosure related to batteries and battery modules may be found in co-owned U.S. Patent Applications entitled “SYSTEM AND METHOD FOR HIGH ENERGY DENSITY BATTERY MODULE” and “SYSTEMS AND METHODS FOR RESTRICTING POWER TO A LOAD TO PREVENT ENGAGING CIRCUIT PROTECTION DEVICE FOR AN AIRCRAFT,” having U.S. patent application Ser. No. 16/948,140 (Attorney Docket No. 1024-038USU1) and Ser. No. 16/590,496 (attorney Docket No. 1024-008USU1), respectively; the entirety of both applications is incorporated herein by reference.

Still referring to FIG. 1, according to some embodiments of the present disclosure, a battery module may be configured to couple to one or more other battery modules, where the combination of two or more battery modules forms at least a portion of battery pack 108. Battery modules may include a plurality of battery cells, as previously discussed in this disclosure. The plurality of battery cells may include any battery cell as described in the entirety of this disclosure. In one or more embodiments, battery module may include a first row of battery cells, where first row of battery cells is in contact with a first side of a thermal conduit (not shown) used to regulate temperatures of abutting battery cells. As a nonlimiting example, row of battery cells may be configured to contain ten columns of battery cells. Further, for example and without limitation, battery unit may include a second row of battery cells, where second row of battery cells may be in contact with a second side of thermal conduit. As a nonlimiting example, second row of battery cells may be configured to contain ten columns of battery cells. In some embodiments, battery module may be configured to contain twenty battery cells in first row and second row. Battery cells of battery module may be arranged in any configuration, such that battery unit may contain any number of rows of battery cells and any number of columns of battery cells. In various embodiments, battery module may contain staggered rows of battery cells. For instance, and without limitation, battery module may contain any offset of distance between first row of battery cells and second row of battery cells, where battery cells of first row and battery cells of second row are not centered with each other. In the instant embodiment, for example and without limitation, battery module may include first row and adjacent second row each containing ten battery cells, each battery cell of first row and each battery cell of second row are shifted a length measuring the radius of a battery cell, wherein the center of each battery cell of first row and each battery cell of second row are separated from the center of the battery cell in the adjacent column by a length equal to the radius of the battery cell. As a further example, and without limitation, each battery cell of first row and each battery cell of second row are shifted a length measuring a quarter the diameter of each battery cell, where the center of each battery cell of first row and each battery cell of second row are separated from the center of a battery cell in the adjacent column by a length equal to a quarter of the diameter of the battery cell. First row of battery cells and second row of battery cells of the at least a battery module may be configured to be fixed in a position by utilizing a cell retainer, as described in the entirety of this disclosure. Each battery cell may be connected utilizing any means of connection as described in the entirety of this disclosure. Persons skilled in the art, upon reviewing the entirety of this disclosure, will be aware of electrical connections that may be used. In some embodiments, battery module and/or battery pack may include thermal conduit that a cooling medium (e.g., coolant) may flow through, wherein thermal conduit has a first surface and a second opposite and opposing surface. In some cases, height of thermal conduit may not exceed the height of battery cells, as described in the entirety of this disclosure. For example, and without limitation, thermal conduit may be at a height that is equal to the height of each battery cell of first row and second row. Thermal conduit may be composed of any suitable material. Thermal conduit is configured to include an indent in the component for each battery cell coupled to the first surface and/or the second surface of thermal conduit. In one or more embodiments, battery pack may include a batter management component to monitor and manage conditions, such as thermal conditions, of battery pack. Additional disclosure related to a battery management component can be found in U.S. patent application Ser. No. 17/529,653 entitled “ELECTRIC AIRCRAFT BATTERY PACK AND METHODS OF USE,” entirety of which in incorporated herein by reference. Additional disclosure related to a battery venting systems and thermal management can be found in U.S. patent application Ser. No. 17/702,195 entitled “SYSTEMS AND METHODS FOR VENTING OF A POWER SOURCE OF AN ELECTRIC VEHICLE,” entirety of which in incorporated herein by reference.

Still referring to FIG. 1, computing device 104 may transmit and/or retrieve measurement data 116 when aircraft is landed or charging. In one or more embodiments, electric aircraft 112 may charge using a charging station 124. Charging of battery pack 108 of electric aircraft 112 may occur in response to receiving a supply or demand request from, for example and without limitation, aircraft personnel, or through a detection of a charging connection being established between electric aircraft and charging station. For instance, and without limitation, a supply request or a demand request may be transmitted to a flight controller of electric aircraft 112. For the purposes of this disclosure, a “supply request” is a signal requesting that power be transferred from battery pack of electric aircraft using charging station. For the purposes of this disclosure, a “demand request” is a signal requesting that power be transferred from charging station to battery pack using charging station. In one or more embodiments, supply request may also include data regarding the amount of power to be transferred between electric aircraft 112 and charging station 124, the price of the transaction, verification data, which may include data regarding the type of electric vehicle and authority to use charging station 124, or the like. In various embodiments, supply request may be transmitted by a remote device or inputted by a user into an interface of electric aircraft 112, charging station 124, or a power grid communicatively connected to charging station 124. In response to the received supply request, a transfer of power from battery pack 108 to grid may be initiated and measurement data 116 may be simultaneously transferred from computing device 104 to first node 120. In some embodiments, measurement data 116 may be received using a data connection and/or charging connector consistent with data connection and/or charging connector described in U.S. patent application Ser. No. 18/096,818 (Attorney Docket No. 1024-678USU1), filed on Jan. 13, 2023, and titled “A SYSTEM OF DATA COMMUNICATION FOR AN ELECTRIC AIRCRAFT,” the entirety of which is incorporated herein by reference. In some embodiments, data connection may include a wireless communication method, such as ethernet, fiber optics, coaxial cable, and the like, or wireless communication, such as radio, WiFi, satellite communication, cable, DSL, LiFi, line-of-sight communication, cellular data, 3G, 4G, LTE, 5G, and the like, or a wired communication method, such as using a communication connection in a charging connector.

Still referring to FIG. 1, in some embodiments, charging station 124 may include a remote computing device 144. In some embodiments, a remote computing device 144 of charging station may generate a battery model using the received measurement data 116 as disclosed later in this disclosure. In some embodiments, charging station 124 may receive measurement data 116 from electric aircraft 112 using a data connection, then transmit the measurement data 116 to a remote computing device 144, wherein remote computing device 144 may then generate the battery model. Charging station 124 may transmit the measurement data 116 to a remote computing device 144 using any wired communication, such as ethernet, fiber optics, coaxial cable, and the like, or wireless communication, such as radio, WiFi, satellite communication, cable, DSL, LiFi, line-of-sight communication, cellular data, 3G, 4G, LTE, 5G, and the like.

Still referring to FIG. 1, in several embodiments, charging station 124 may be used to discharge battery pack 108. For the purpose of this disclosure, a “charging station” is a device configured to facilitate delivery of electrical power to an electric aircraft. For instance, and without limitation, charging station may be configured to facilitate delivery of an electrical power between an electric aircraft 112 and a power grid. In another instance, charging station may be configured to facilitate delivery of electrical power between a power source of electric charging station 124 and electric aircraft 112. In some embodiments, charging station may include a charger. For the purposes of this disclosure, an “electric aircraft” is an aircraft that is configured to fly primarily using electricity. In one or more embodiments, electric aircraft 112 may be electrically connected to charging station 124 during charging of battery pack 108 of electric aircraft 112. Charging station 124 may include an infrastructure that allows for the recharging of one or more power sources of electric aircraft 112. Charging station may have a plurality of connections to comply with various electric aircraft needs. In one embodiment, charging station may switch between power transfer standards, such as the combined charging system standard (CCS) and CHAdeMO standards. In another embodiment, charging station may adapt to multiple demand response interfaces. Charging station may include an ADR 2.0 as a demand response interface.

With continued reference to FIG. 1, in some embodiments, computing device 104 may be included in charging station 124. In such cases, measurement data 116 may be transmitted through a charging connection between electric aircraft 112 and charging station 124. In one or more embodiments, charging connection may include a bidirectional charging connection. For the purposes of this disclosure, a “bidirectional charging connection” is a connection associated with transfer of electrical power between a power source of an electric aircraft and a charging station, where the transfer of electrical power may occur in either direction. For instance, and without limitation, bidirectional charging connection may facilitate a transfer of power between a battery pack 108 of electric aircraft 112 and a power source of charging station and/or a power grid. For the purposes of this disclosure, a “power source” is a device configured to generate, store, or provide electrical energy. Charging connection may be a wired or wireless connection. Charging connection may include a communication between power grid and electric aircraft 104 that is created by electric aircraft 112 being connected to charging station, as discussed further in this disclosure. For example, and without limitation, one or more communications between charging station, power grid, and electric aircraft may be facilitated by charging connection. As used in this disclosure, “communication” is an attribute where two or more relata interact with one another, for example, within a specific domain or in a certain manner. In some cases, communication between two or more relata may be of a specific domain, such as, and without limitation, electric communication, fluidic communication, informatic communication, mechanic communication, and the like. As used in this disclosure, “electric communication” is an attribute wherein two or more relata interact with one another by way of an electric current or electricity in general. For example, and without limitation, a communication between charging station 124 and electric aircraft 112 may include an electric communication, where a current flows between charging station 124 and electric aircraft 112. As used in this disclosure, “informatic communication” is an attribute wherein two or more relata interact with one another by way of an information flow or information in general. For example, an informatic communication may include a sensor of charging station, electric aircraft 112, or a remote device that provides information to a computing device 104 of electric aircraft 112. In another example, and without limitation, an informatic communication may include a request signal, such as a demand request or a supply request, being transmitted between power grid, electric aircraft 112, and/or charging station 124. As used in this disclosure, “mechanic communication” is an attribute wherein two or more relata interact with one another by way of mechanical means, for instance mechanic effort (e.g., force) and flow (e.g., velocity). For example, a fastener of a connector of charging station may physically mate with a port of electric aircraft 112 to create a mechanic communication between electric aircraft 112 and charging station 124. For the purposes of this disclosure, a “connector” is a component of a charging station that mechanically connects to a device or system to create a charging connection between the charging station and the device or system. Still referring to FIG. 1, in one or more embodiments, communication of charging connection, or any connections between nay devices or systems of apparatus 100, may include various forms of communication. For instance, communication of a charging connection may include a wireless communication. For example, and without, charging connection may include an informatic communication where electric aircraft 112 may transmit a demand request and/or data to charging station 124 via a wireless communication. In one or more embodiments, charging connection includes an electric connection between electric aircraft 112 and charging station 124, as discussed further in this disclosure. Charging connection may include a vehicle-to-grid (V2G) charging connection, a grid-to-vehicle (G2V) charging connection, or combination thereof. A V2G system may include a bidirectional electric vehicle charging station such as a trickle charger and may be used to supply power from an electric aircraft's battery to an electric grid via a DC-to-AC converter system usually embedded in a charging station. In a non-limiting embodiment, V2G may be used to balance and settle local, regional, or national energy needs via smart charging. Additionally, charging connection may include a vehicle-to-home (V2H) charging. Charging station 124 may include, but is not limited to, a constant voltage charger, a constant current charger, a taper current charger, a pulsed current charger, a negative pulse charger, an IUI charger, throttle charger, and a float charger.

Still referring to FIG. 1, a wireless communication may be used to transmit measurement data to or from computing device 104. Wireless communication of measurement data may be done while electric aircraft 112 is in operation (e.g., inflight), when electric aircraft is not in operation, or when electric aircraft is charging, as previously mentioned. For instance, and without limitation, a multi-node network may be used to communicate measurement data between electric aircraft 112 and one or more remote computing devices during flight of electric aircraft 112. A multi-node network may include a mesh network, for instance and without limitation, as described in U.S. Nonprovisional application Ser. No. 17/478,067 filed Sep. 17, 2021, titled “SYSTEM FOR A MESH NETWORK FOR USE IN AIRCRAFTS,” the entirety of which is incorporated herein by reference. In one or more embodiments, apparatus may include a plurality of nodes. Plurality of nodes may include a first node 128, a second node 132, a third node 136, a fourth node 140, and so on. In one or more embodiments, computing device 104 may include a first node 128. Plurality of nodes may transfer data between each other using a communicative connection, such as communication connection 160. Communicative connected facilitates the plurality of nodes being communicatively connected as described further in this disclosure. First node 128 may be configured to transmit (e.g., retrieve) data, such as measurement data, to one or more other nodes of a network of apparatus 100. For instance, and without limitation, first node 128 may be configured to transmit measurement data 116 to at least a second node 132. In some embodiments, second node 132 may include a remote computing device 144, as discussed previously in this disclosure. In other embodiments, first node 128 may be configured to transmit measurement data to a third node 136. In some embodiments, computing device 104 may be configured to transmit measurement data to a third node 136. In various embodiments, third node 136 may include a cloud database 142. In some embodiments, computing device 104 may be configured to transmit measurement data to a fourth node 140. In various embodiments, fourth node 140 may include charging station 124. As understood by one skilled in the art, apparatus 100 may include any number of nodes. For instance, and without limitation, apparatus 100 may include a plurality of nodes, where each node includes a different electric aircraft, where each electric aircraft includes a battery pack. In various embodiments, computing device 104 may retrieve measurement data from each electric aircraft such that computing device retrieves a plurality of measurement data from a plurality of aircraft. For example, and without limitation, a first node may include a first aircraft, a second node, may include a second aircraft, a third node may include a third aircraft, a fourth node may include a fourth aircraft. First measurement data from first electric aircraft may be retrieved by computing device 104, second measurement data from second electric aircraft may be retrieved by computing device 104, third measurement data from third electric aircraft may be retrieved by computing device 104, and fourth measurement data from fourth electric aircraft may be retrieved by computing device 104.

Still referring to FIG. 1, apparatus 100 may include a first node 128, as previously discussed. In a non-limiting embodiment, first node 128 may include computing device 104. First node 128 may include any computing device as described in this disclosure, including without limitation a microcontroller, microprocessor, digital signal processor (DSP) and/or system on a chip (SoC) as described in this disclosure. First node 128 may include, be included in, and/or communicate with a mobile device such as a mobile telephone or smartphone. First node 128 may include a single computing device operating independently, or may include two or more computing device operating in concert, in parallel, sequentially or the like; two or more computing devices may be included together in a single computing device or in two or more computing devices. First node 128 may interface or communicate with one or more additional devices as described below in further detail via a network interface device. Network interface device may be utilized for connecting first node 128 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. First node 128 may include but is not limited to, for example, a computing device or cluster of computing devices in a first location and a remote computing device or cluster of computing devices in a second location. First node 128 may include one or more computing devices dedicated to data storage, security, distribution of traffic for load balancing, and the like. For example, and without limitation, first node 128 may include a plurality of computing devices similar to computing device 104, where each computing device is communicatively connected to a corresponding battery pack of an electric aircraft and may transmit measurement data associated with corresponding battery packs. First node 128 may distribute one or more computing tasks as described below across a plurality of computing devices of computing device, which may operate in parallel, in series, redundantly, or in any other manner used for distribution of tasks or memory between computing devices. First node 128 may be implemented using a “shared nothing” architecture in which data is cached at the worker, in an embodiment, this may enable scalability of apparatus 100 and/or computing device.

With continued reference to FIG. 1, first node 128 may be designed and/or configured to perform any method, method step, or sequence of method steps in any embodiment described in this disclosure, in any order and with any degree of repetition. For instance, first node 128 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. First node 128 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

Still referring to FIG. 1, apparatus 100 may include a plurality of nodes. In some embodiments, apparatus 100 may include and/or communicate with a first node 128. In some embodiments, apparatus 100 may include and/or communicate with a second node 132. In some embodiments, apparatus 100 may include and/or communicate with a third node 136. In some embodiments, apparatus 100 may include and/or communicate with a fourth node 140. A “node” as used in this disclosure is a computing device that is configured to receive, retrieve, and/or transmit data to another device, system, or cloud. A “cloud” or “cloud database”, for the purposes of this disclosure, is a database that can be accessed through a cloud environment, which allows for remote access and interaction. For instance, and without limitation, nodes may include any computing device, such as, but not limited to, an electric aircraft, a laptop, a smartphone, a tablet, a command deck, a recharging pad, and/or other computing devices. In some embodiments, first node 128 may include a flight controller of an electric aircraft. In other embodiments, first node 128 may include computing device 104. In some embodiments, first node 128, second node 132, third node 136, and fourth node 140 may include a flight controller of an electric aircraft. In some embodiments, an electric aircraft may include an unmanned aerial vehicle (UAV), eVTOL, quadcopter, or other vehicle. In some embodiments, first node 128 may be configured to transmit and receive data from second node, third node, and/or fourth node. In some embodiments, second node 132 may be configured to transmit and receive data from node, third node, fourth node, and so on. In some embodiments, third node may be configured to transmit and receive data from node, second node, and/or fourth nod. In some embodiments, fourth node may be configured to transmit and receive data from first node 120, second node, and/or third node. Apparatus 100 may include and/or communicate with a plurality of nodes greater than four nodes. In some embodiments, apparatus 100 may include less than four nodes. A node of apparatus 100 may be configured to communicate data to another node of apparatus 100. Data may include, but is not limited to, flight path data, battery charge data, locational data, speed data, acceleration data, propulsor data, power data, and/or other data. In some embodiments, data may include communication efficiency feedback. “Communication efficiency feedback,” as used in this disclosure, is any data concerning effectiveness of data transmission. In some embodiments, communication efficiency feedback may include, but is not limited to, signal strength, signal-noise ratio, error rate, availability of a higher-efficiency mode, physical trajectory of a second node, project change over time, relative strength of a third node, and the like. In some embodiments, apparatus 100 may include and/or communicate with an initial recipient node. An “initial recipient node” as used in this disclosure is any node first transmitted to in a network. In some embodiments, first node 120 may include an initial recipient node. First node 120 may transmit data to second node 132. Second node 132 may transmit communication efficiency feedback to another node of apparatus 100. In some embodiments, communication efficiency feedback may be based on data transmission times between two or more nodes. Communication efficiency feedback may be explicit. Explicit communication efficiency feedback may include second node 132 providing information to first node 120 about transmission times, error rates, signal-noise ratios, and the like. In some embodiments, second node 132 may provide communication efficiency feedback to first node 120 about one or more other nodes in apparatus 100. Communication efficiency feedback about one or more other nodes of apparatus 100 may include, but is not limited to, transmission speed, signal strength, error rate, signal-noise ratio, physical trajectory, availability, projected change over time, and the like. First node 120 may use communication efficiency feedback of second node 132 and/or one or more other nodes of apparatus 100 to select an initial recipient node. Communication efficiency feedback may alternatively or additionally be implicit. Implicit communication efficiency feedback may include first node 120 detecting communication parameters such as, but not limited to, transmission speed, error rate, signal strength, physical trajectory, signal-noise ratio, and the like. First node 120 may determine one or more communication parameters based on a transmission between first node 120 and one or more other nodes of apparatus 100. In some embodiments, first node 120 may store communication parameters of one or more other nodes. In a non-limiting example, first node 120 may store communication parameters of second node 132 which may include that second node 132 may have a high signal-noise ratio. First node 120 may search for another node of apparatus 100 to select as an initial recipient node based on stored communication parameters of second node 132. In some embodiments, first node 120 may compare one or more communication parameters of a communication efficiency feedback of one or more nodes to select an initial recipient node. First node 120 may compare communication efficiency feedback to a communication threshold. A “communication threshold” as used in this disclosure is any minimum or maximum value of a communication metric. A communication threshold may include, but is not limited to, an error rate, a transmission speed, a signal-noise ratio, a physical trajectory, a signal strength, and the like. In some embodiments, first node 120 may receive data from second node 132 about a third node, fourth node, etc. Data about a third node, fourth node, etc. may include communication efficiency feedback. First node 120 may use data received from second node 132 about another node to select from a plurality of nodes of apparatus 100. First node 120 may utilize a machine-learning model to predict an optimal communication pathway of nodes. A machine-learning model may be trained on training data correlating communication parameters to selected initial recipient nodes. Training data may be obtained from prior transmissions, stored data of one or more nodes, and/or received from an external computing device. In some embodiments, training data may be obtained from a user input. First node 120 may utilize a machine-learning model to compare one or more nodes based on one or more communication parameters for an optimal pathway selection.

Still referring to FIG. 1, first node 120 may use an objective function to compare second node 132 to one or more other nodes. Generation of an objective function may include generation of a function to score and weight factors to achieve a communication score for each feasible pairing. In some embodiments, pairings may be scored in a matrix for optimization, where columns represent nodes and rows represent communications potentially paired therewith; each cell of such a matrix may represent a score of a pairing of the corresponding node to the corresponding communication. In some embodiments, assigning a predicted process that optimizes the objective function includes performing a greedy algorithm process. A “greedy algorithm” is defined as an algorithm that selects locally optimal choices, which may or may not generate a globally optimal solution. For instance, first node 120 may select pairings so that scores associated therewith are the best score for each order and/or for each process. In such an example, optimization may determine the combination of processes such that each object pairing includes the highest score possible.

Still referring to FIG. 1, first node 120 may use a fuzzy inference system to determine a plurality of outputs based on a plurality of inputs. A plurality of outputs may include a communication efficiency of one or more nodes. A plurality of inputs may include communication efficiency feedback as described above. In a non-limiting example, first node 120 may detect that second node 132 may have slow response time and a far physical trajectory. First node 120 may determine, using fuzzy logic, that second node 132 is “too far” for selection as an initial recipient node. In another non-limiting example, first node 120 may detect that second node 132 may have a high transmission speed and a close physical trajectory. First node 120 may determine that second node 132 has a “strong signal”.

Still referring to FIG. 1, first node 120 may determine a connectivity of a plurality of potential initial recipient nodes. First node 120 may determine, using any process described in this disclosure, an optimal initial recipient node according to a selection criteria. A selection criteria may include, but is not limited to, physical trajectory, projected change over time, signal strength, error rate, transmission speeds, response times, neighboring nodes, and the like. In some embodiments, each node of apparatus 100 may iteratively ID initial recipient nodes and calculate a best option score and an average score. Each node may send a best option score and/or an average score to all nodes of apparatus 100. A node of apparatus 100 may calculi and update a best option score and/or an average score based on data received from other nodes of apparatus 100. In some embodiments, by having each node update a best option score and average score of their own initial recipient nodes, first node 128 may select an initial recipient node based on robustness and speed of each possible pathway of other nodes of apparatus 100.

In some embodiments, and continuing to refer to FIG. 1, first node 128 may be generated from a computing device 104. In some embodiments, all nodes of apparatus 100 may be generated from a flight controller of an aircraft. In some embodiments, one node of apparatus 100 may be generated from an aircraft and another node may be generated from a landing pad and/or charging station. In some embodiments, a first node 128 may be generated from an electric aircraft and may communicate charging data to second node which may be generated from a charging infrastructure. An electric aircraft may communicate with a charging infrastructure through one or more nodes of apparatus 100. Communication between an electric aircraft and a charging infrastructure may include, but is not limited to, data communication about charge status of an electric aircraft, charging standards of an electric aircraft, charging compatibility of the charger and the electric aircraft, estimated charging times, and the like.

Still referring to FIG. 1, in some embodiments, apparatus 100 may include, participate in, and/or be incorporated in a network topology. A “network topology” as used in this disclosure is an arrangement of elements of a communication network. In some embodiments, apparatus 100 may include, but is not limited to, a star network, tree network, and/or a mesh network. A “mesh network” as used in this disclosure is a local network topology in which the infrastructure nodes connect directly, dynamically, and non-hierarchically to as many other nodes as possible. Nodes of apparatus 100 may be configured to communicate in a partial mesh network. A partial mesh network may include a communication system in which some nodes may be connected directly to one another while other nodes may need to connect to at least another node to reach a third node. In some embodiments, apparatus 100 may be configured to communicate in a full mesh network. A full mesh network may include a communication system in which every node in the network may communicate directly to one another. In some embodiments, apparatus 100 may include a layered data network. As used in this disclosure a “layered data network” is a data network with a plurality of substantially independent communication layers with each configured to allow for data transfer over predetermined bandwidths and frequencies. As used in this disclosure a “layer” is a distinct and independent functional and procedural tool of transferring data from one location to another. For example, and without limitation, one layer may transmit communication data at a particular frequency range while another layer may transmit communication data at another frequency range such that there is substantially no cross-talk between the two layers which advantageously provides a redundancy and safeguard in the event of a disruption in the operation of one of the layers. A layer may be an abstraction which is not tangible.

Still referring to FIG. 1, in some embodiments, apparatus 100 may include first node 128, second node 132, third node 136, and/or fourth node 140, as previously mentioned in this disclosure. First node 128 may be configured to communicate with a first layer providing radio communication between nodes at a first bandwidth. In some embodiments, first node 128 may be configured to communicate with a second layer providing mobile network communication between the nodes at a second bandwidth. In some embodiments, first node 128 may be configured to communicate with a third layer providing satellite communication between the nodes at a third bandwidth. In some embodiments, any node of apparatus 100 may be configured to communicate with any layer of communication. In some embodiments, a node of apparatus 100 may include an antenna configured to provide radio communication between one or more nodes. For example, and without limitation, an antenna may include a directional antenna. In an embodiment, apparatus 100 may include a first bandwidth, a second bandwidth, and a third bandwidth. In some embodiments, apparatus 100 may include more or less than three bandwidths. In some embodiments, a first bandwidth may be greater than a second bandwidth and a third bandwidth. In some embodiments, apparatus 100 may be configured to provide mobile network communication in the form a cellular network, such as, but not limited to, 2G, 3G, 4G, 5G, LTE, and/or other cellular network standards.

Still referring to FIG. 1, radio communication, in accordance with embodiments, may utilize at least a communication band and communication protocols suitable for aircraft radio communication. For example, and without limitation, a very-high-frequency (VHF) air band with frequencies between about 108 MHz and about 137 MHz may be utilized for radio communication. In another example, and without limitation, frequencies in the Gigahertz range may be utilized. Airband or aircraft band is the name for a group of frequencies in the VHF radio spectrum allocated to radio communication in civil aviation, sometimes also referred to as VHF, or phonetically as “Victor”. Different sections of the band are used for radio-navigational aids and air traffic control. Radio communication protocols for aircraft are typically governed by the regulations of the Federal Aviation Authority (FAA) in the United States and by other regulatory authorities internationally. Radio communication protocols may employ, for example and without limitation an S band with frequencies in the range from about 2 GHz to about 4 GHz. For example, and without limitation, for 4G mobile network communication frequency bands in the range of about 2 GHz to about 8 GHz may be utilized, and for 5G mobile network communication frequency bands in the ranges of about 450 MHz to about 6 GHz and of about 24 GHz to about 53 GHz may be utilized. Mobile network communication may utilize, for example and without limitation, a mobile network protocol that allows users to move from one network to another with the same IP address. In some embodiments, a node of apparatus 100 may be configured to transmit and/or receive a radio frequency transmission signal. A “radio frequency transmission signal,” as used in this disclosure, is an alternating electric current or voltage or of a magnetic, electric, or electromagnetic field or mechanical system in the frequency range from approximately 20 kHz to approximately 300 GHz. A radio frequency (RF) transmission signal may compose an analogue and/or digital signal received and be transmitted using functionality of output power of radio frequency from a transmitter to an antenna, and/or any RF receiver. A RF transmission signal may use longwave transmitter device for transmission of signals. An RF transmission signal may include a variety of frequency ranges, wavelength ranges, ITU designations, and IEEE bands including HF, VHF, UHF, L, S, C, X, Ku, K, Ka, V, W, mm, among others.

Still referring to FIG. 1, satellite communication, in accordance with embodiments, may utilize at least a communication band and communication protocols suitable for aircraft satellite communication. For example, and without limitation, satellite communication bands may include L-band (1-2 GHz), C-band (4-8 GHz), X-band (8-12 GHz), Ku-band (12-18 GHz), Ku-band (12-18 GHz), and the like, among others. Satellite communication protocols may employ, for example and without limitation, a Secondary Surveillance Radar (SSR) system, automated dependent surveillance-broadcast (ADS-B) system, or the like. In SSR, radar stations may use radar to interrogate transponders attached to or contained in aircraft and receive information in response describing such information as aircraft identity, codes describing flight plans, codes describing destination, and the like SSR may utilize any suitable interrogation mode, including Mode S interrogation for generalized information. ADS-B may implement two communication protocols, ADS-B-Out and ADS-B-In. ADS-B-Out may transmit aircraft position and ADS-B-In may receive aircraft position. Radio communication equipment may include any equipment suitable to carry on communication via electromagnetic waves at a particular bandwidth or bandwidth range, for example and without limitation, a receiver, a transmitter, a transceiver, an antenna, an aerial, and the like, among others. A mobile or cellular network communication equipment may include any equipment suitable to carry on communication via electromagnetic waves at a particular bandwidth or bandwidth range, for example and without limitation, a cellular phone, a smart phone, a personal digital assistant (PDA), a tablet, an antenna, an aerial, and the like, among others. A satellite communication equipment may include any equipment suitable to carry on communication via electromagnetic waves at a particular bandwidth or bandwidth range, for example and without limitation, a satellite data unit, an amplifier, an antenna, an aerial, and the like, among others.

Still referring to FIG. 1, as used in this disclosure “bandwidth” is measured as the amount of data that can be transferred from one point or location to another in a specific amount of time. The points or locations may be within a given network. Typically, bandwidth is expressed as a bitrate and measured in bits per second (bps). In some instances, bandwidth may also indicate a range within a band of wavelengths, frequencies, or energies, for example and without limitation, a range of radio frequencies which is utilized for a particular communication.

Still referring to FIG. 1, as used in this disclosure “antenna” is a rod, wire, aerial or other device used to transmit or receive signals such as, without limitation, radio signals and the like. A “directional antenna” or beam antenna is an antenna which radiates or receives greater power in specific directions allowing increased performance and reduced interference from unwanted sources. Typical examples of directional antennas include the Yagi antenna, the log-periodic antenna, and the corner reflector antenna. The directional antenna may include a high-gain antenna (HGA) which is a directional antenna with a focused, narrow radio wave beamwidth and a low-gain antenna (LGA) which is an omnidirectional antenna with a broad radio wave beamwidth, as needed or desired.

With continued reference to FIG. 1, as used in this disclosure, a “signal” is any intelligible representation of data, for example from one device to another. A signal may include an optical signal, a hydraulic signal, a pneumatic signal, a mechanical, signal, an electric signal, a digital signal, an analog signal and the like. In some cases, a signal may be used to communicate with a computing device, for example by way of one or more ports. In some cases, a signal may be transmitted and/or received by a computing device for example by way of an input/output port. An analog signal may be digitized, for example by way of an analog to digital converter. In some cases, an analog signal may be processed, for example by way of any analog signal processing steps described in this disclosure, prior to digitization. In some cases, a digital signal may be used to communicate between two or more devices, including without limitation computing devices. In some cases, a digital signal may be communicated by way of one or more communication protocols, including without limitation internet protocol (IP), controller area network (CAN) protocols, serial communication protocols (e.g., universal asynchronous receiver-transmitter [UART]), parallel communication protocols (e.g., IEEE 128 [printer port]), and the like.

Still referring to FIG. 1, in some cases, a node of apparatus 100 may perform one or more signal processing steps on a sensed characteristic. For instance, a node may analyze, modify, and/or synthesize a signal representative of characteristic in order to improve the signal, for instance by improving transmission, storage efficiency, or signal to noise ratio. Exemplary methods of signal processing may include analog, continuous time, discrete, digital, nonlinear, and statistical. Analog signal processing may be performed on non-digitized or analog signals. Exemplary analog processes may include passive filters, active filters, additive mixers, integrators, delay lines, compandors, multipliers, voltage-controlled filters, voltage-controlled oscillators, and phase-locked loops. Continuous-time signal processing may be used, in some cases, to process signals which varying continuously within a domain, for instance time. Exemplary non-limiting continuous time processes may include time domain processing, frequency domain processing (Fourier transform), and complex frequency domain processing. Discrete time signal processing may be used when a signal is sampled non-continuously or at discrete time intervals (i.e., quantized in time). Analog discrete-time signal processing may process a signal using the following exemplary circuits sample and hold circuits, analog time-division multiplexers, analog delay lines and analog feedback shift registers. Digital signal processing may be used to process digitized discrete-time sampled signals. Commonly, digital signal processing may be performed by a computing device or other specialized digital circuits, such as without limitation an application specific integrated circuit (ASIC), a field-programmable gate array (FPGA), or a specialized digital signal processor (DSP). Digital signal processing may be used to perform any combination of typical arithmetical operations, including fixed-point and floating-point, real-valued and complex-valued, multiplication and addition. Digital signal processing may additionally operate circular buffers and lookup tables. Further non-limiting examples of algorithms that may be performed according to digital signal processing techniques include fast Fourier transform (FFT), finite impulse response (FIR) filter, infinite impulse response (IIR) filter, and adaptive filters such as the Wiener and Kalman filters. Statistical signal processing may be used to process a signal as a random function (i.e., a stochastic process), utilizing statistical properties. For instance, in some embodiments, a signal may be modeled with a probability distribution indicating noise, which then may be used to reduce noise in a processed signal. Any datum or signal herein may include an electrical signal. Electrical signals may include analog signals, digital signals, periodic or aperiodic signal, step signals, unit impulse signal, unit ramp signal, unit parabolic signal, signum function, exponential signal, rectangular signal, triangular signal, sinusoidal signal, sinc function, or pulse width modulated signal. Sensor 120 may include circuitry, computing devices, electronic components or a combination thereof that translates a plurality of datum into at least an electronic signal configured to be transmitted to another electronic component.

Still referring to FIG. 1, in some embodiments, computing device 104 may be configured to provide fleet data 148 as a function of measurement data 116. For instance, computing device 104 may provide fleet data 148 as a function of one or more measurement data associated with one or more battery packs of electric aircraft. For the purposes of this disclosure, “fleet level data” or “fleet data” is compiled and/or or combined measurement data, wherein the fleet data includes or incorporates measurement data from a plurality of electric aircraft. In various embodiments, fleet data 148 may include compiled logistical information describing battery packs of a fleet of electric aircraft, where a fleet of aircraft includes a plurality of aircraft. Computing device 104, or any other computing device of apparatus 100, may be configured to compile measurement data 116 of electric aircraft with other measurement data from other electric aircraft. For instance, and without limitation, battery pack 108 may include a plurality of battery packs (e.g., first battery pack, second battery pack, third battery pack, fourth battery pack, and so on) and electric aircraft 112 may include a plurality of electric aircraft (e.g., first electric aircraft, second electric aircraft, third electric aircraft, fourth electric aircraft, and so on). First measurement data associated with a first battery pack of first electric aircraft may be combined with second measurement data associated with a second battery pack of the same electric aircraft (e.g., first electric aircraft) or a second electric aircraft. For example, and without limitation, a plurality of measurement data from various battery packs may be used to form fleet level data. As a non-limiting example, SoC data of measurement data may be combined with SoC data from a plurality of battery packs from multiple electric aircraft to form fleet data 148. This fleet data 148 may give a better picture of the performance of battery packs across a fleet of electric aircraft. In some embodiments, measurement data may be combined and/or concatenated with like measurement data from a plurality of electric aircraft to form fleet data 148. Fleet level data may be used by both consumers and operators to view logistical information of battery packs of electrical aircraft, such as operating statistics of one or more powers sources of electrical aircraft.

Still referring to FIG. 1, computing device 104 is configured to generate a battery model 152 as a function of fleet data 148. For the purposes of this disclosure, a “battery model” is a mathematical model that describes a physical battery system. In some embodiments, battery model may model a battery cell, battery module, battery pack, battery system, and/or any other combination of batteries. In one or more embodiments, mathematical model may include various equations that described physical aspects of battery pack. In some embodiments, performance analytics of battery pack may be determined using an algorithm, such that the algorithm uses fleet data and battery model 152 as inputs and outputs the performance analytics. In one embodiment, the performance analytics may be generated as a function of a performance machine-learning process. In one embodiment, computing device 104 is configured to utilize neural networks to generate one or more performance analytics. Battery model 152 may include a plurality of battery models capable of producing at least the performance analytics and/or parameters of battery pack. In a nonlimiting example, an electrochemical modeling, such as a “Newman Pseudo two-dimensional (2D) model”, may be used. In one embodiment, battery model 152 may include a heat generation model. In some embodiments, the battery model 152 may be produced as a function of a machine-learning process, as described further in this disclosure.

Additionally, or alternatively, and continuing to refer to FIG. 1, in embodiments, a machine-learning process, such as battery model 152, may be trained using a set of training data. “Training data” may include initial fleet data correlated to performance analytics. In an embodiment, training data may include past correlations of fleet data and performance analytics for the same aircraft or may include past correlations for other electric aircrafts. For instance, and without limitation, training data may include initial fleet data which is a function of initial measurement data associated with battery pack, that is correlated with performance analytics. “Initial measurement data” is, for the purposes of this disclosure, measurement data used to identify initial fleet data. “Initial fleet data” is, for the purposes of this disclosure, fleet data used to generate battery model. In one or more embodiments, current fleet data or current measurement data may be inputted into battery model so that performance analytics may be outputted by battery model. For the purposes of this disclosure, “current measurement data” is measurement data used to identify current fleet data. For the purposes of this disclosure, “current fleet data” is fleet data collected for the purposes of determining an operating condition of a battery pack, as discussed further in this disclosure. In one or more embodiments, current measurement data and current fleet data includes real-time measurement data and real-time fleet data, respectively. In some embodiment, training data may be stored in a data store system, which may include, for example, memory of controller and/or cloud database 142. In some embodiments, data store system may be a remote database communicatively connected to apparatus 100 and/or computing device 104. In a nonlimiting example, a database, such as a database of memory of computing device 104, may include a database containing training data that is updated against a remote database, such as cloud database 142, when it becomes communicatively connected to the remote database, or at preset time intervals. For instance, and without limitation, training data may be updated when electric aircraft 112 is connected to and/or in electric communication with charging station 124. In some embodiments, apparatus 100 may be configured to update training data database whenever apparatus 100 complies fleet data. In an embodiment, apparatus 100 may be configured to correlate data whenever it generates fleet data. In some embodiments, apparatus 100 may further be configured to update training data database with correlated data. In some embodiments, battery model and/or machine-learning model may be trained as a function of training data. Battery model 152 and machine-learning model, and training those models, are consistent with the machine-learning model, and neural network, described further below.

Still referring to FIG. 1, computing device 104 may be configured to provide performance analytics 156 as a function of battery model 152. For instance, and without limitation, battery model 152 may be used to create a lookup table that includes performance analytics 156. For the purposes of this disclosure, a “lookup table” is a formatted relationship between measurement and/or fleet data and performance analytics. Lookup table may be used as reference by computing device and or a BMS of battery pack. Lookup table may be used by a computing device to relate a variable to one or more outputs. For example, and without limitation, a flight controller of an electric aircraft may “look up” a measured voltage value to quickly determine an (estimated) SoC. Lookup table may be created or generated by collecting (e.g., storing in a database) inputs (e.g., measurement data or fleet data) and outputs (e.g., performance analytics) of battery model 152 for particular, related variables at a particular resolution. “Performance analytics,” for the purposes of this disclosure, is to a collection of information or parameters representing any detailed organization and implementation of an operation of a battery pack. Thus, performance analytics may include a quantitative value or parameter of battery pack as a function of one or more current or real-time characteristics, such as current measurement data or current fleet data, of battery pack. For example, and without limitation, a voltage performance analytic may include a numerical or quantitative value of voltage based upon parameters of battery pack, such as current, resistance, and the like. More specifically a current measurement data may include a real-time value of current (I) and resistance (R) which may be inputted into battery model, such as a lookup table of battery model, to identify voltage of battery pack as a function of the current measurement data. In a non-limiting embodiment, current measurement data may include unique identification numbers assigned to each battery pack. In a non-limiting embodiment, performance analytics 156 may include a historical record of locations and/or uses corresponding to battery pack. performance analytics 156 may include time of usage or dormancy of battery pack. Performance analytics 156 may include a history of health information of one or more battery packs. In a non-limiting embodiment, a history of health of battery pack may be measured with the ability to be presented in a visual format to a user, such as a visual representation of performance analytics 156 shown on a display using a graphical user interface (GUI). A “graphical user interface”, for the purposes of this disclosure, is a user interface that allows users to interact with electronic devices. Performance analytics 156 may include potential health data or potential data of electric aircraft and/or electric aircraft parts that may be incorporated on to an electric aircraft. For example, and without limitation, measurement data and/or fleet data may include one or more values related to voltage discharge over a duration of time and/or during various pilot inputs, and performance analytics may include DoD or anode or cathode health as a function of such measurement data and/or or fleet data. A person of ordinary skill in the art, after viewing the entirety of this disclosure, would appreciate the type of data measured in the context of aircraft logistics.

In some embodiments, and continuing to refer to FIG. 1, a machine-learning model, such as battery model 152, may be used to determine performance analytics 156. Machine-learning model may include training data may include past correlations of fleet data and/or measurement data and performance analytics 156. In some embodiments, training data includes correlations for fleet data and performance analytics. For instance, and without limitation, training data may include measurement and/or fleet inputs and performance analytic outputs. In some embodiments, training data may be stored in a data store system coupled to computing device. In some embodiments, data store system may be a remote database communicatively connected to one or more components of apparatus 100. In some embodiments, apparatus 100 may be configured to update training data database whenever the apparatus 100 generates performance analytics and/or receives updated measurement and/or fleet data. In an embodiment, apparatus 100 may be configured to correlate data whenever it generates performance analytics. In some embodiment, apparatus 100 may further be configured to store correlated data in a local data store system, such as cloud database. In some embodiments, apparatus 100 may further be configured to iteratively update training data database with correlated data (e.g., updated measurement data and/or updated fleet data). In some embodiments, the machine-learning model may be trained as a function of the training data.

With continued reference to FIG. 1, sensor 120 is configured to detect measurement data, which may include one or more measured aircraft operation datum including a pilot data 116. A “pilot data,” for the purposes of this disclosure, refer to any datum that represent a state of information of a pilot of an electric aircraft. Pilot data 116 may include any datum that refers to at least an element of data identifying and/or a pilot input or command. In some embodiments, performance analytics 156 may be determined as a function of fleet data and pilot data. In this case, performance analytics 156 may include information indicating how actions of an operator, such as a pilot, affects a condition of one or more battery packs of apparatus 100. At least pilot control may be communicatively connected to any other component presented in system, the communicative connection may include redundant connections configured to safeguard against single-point failure. Pilot input may indicate a pilot's desire to change the heading or trim of an electric aircraft. Pilot input may indicate a pilot's desire to change an aircraft's pitch, roll, yaw, or throttle. Aircraft trajectory is manipulated by one or more control surfaces and propulsors working alone or in tandem consistent with the entirety of this disclosure, hereinbelow. Pitch, roll, and yaw may be used to describe an aircraft's attitude and/or heading, as they correspond to three separate and distinct axes about which the aircraft may rotate with an applied moment, torque, and/or other force applied to at least a portion of an aircraft. Pilot data 116 may include any information describing the movement and actions of the pilot during a flight. In a non-limiting embodiment, pilot data 116 may record any buttons or electrical component that the pilot may have completed an action upon. The record of the actions may be used by the flight controller 120 to map a flight simulation which may include a general simulation of the pilot's actions and movements. A person of ordinary skill in the art, after viewing the entirety of this disclosure, would appreciate the monitoring and mapping of a pilot's movements and actions in the context of simulation.

With continued reference to FIG. 1, the pilot data 116 may include a pilot input and/or pilot control that may include an electrical. Any pilot input as described herein may be consistent with any pilot input as described in U.S. patent application Ser. No. 17/218,387 filed on Mar. 31, 2021, and titled, “METHOD AND SYSTEM FOR FLY-BY-WIRE FLIGHT CONTROL CONFIGURED FOR USE IN ELECTRIC AIRCRAFT,” which is incorporated herein in its entirety by reference. Pilot input may include a pilot control which may include a throttle wherein the throttle may be any throttle as described herein, and in non-limiting examples, may include pedals, sticks, levers, buttons, dials, touch screens, one or more computing devices, and the like. Additionally, a right-hand floor-mounted lift lever may be used to control the amount of thrust provided by the lift fans or other propulsors. The rotation of a thumb wheel pusher throttle may be mounted on the end of this lever and may control the amount of torque provided by the pusher motor, or one or more other propulsors, alone or in combination. Any throttle as described herein may be consistent with any throttle described in U.S. patent application Ser. No. 16/929,206 filed on Jul. 15, 2020, and titled, “A HOVER AND THRUST CONTROL ASSEMBLY FOR DUAL-MODE AIRCRAFT”, which is incorporated herein in its entirety by reference. Sensor 120 may be mechanically and communicatively connected to an inceptor stick. The pilot input may include a left-hand strain-gauge style STICK for the control of roll, pitch and yaw in both forward and assisted lift flight. A 4-way hat switch on top of the left-hand stick enables the pilot to set roll and pitch trim. Any inceptor stick described herein may be consistent with any inceptor or directional control as described in U.S. patent application Ser. No. 17/001,845 filed on Aug. 25, 2020, and titled, “A HOVER AND THRUST CONTROL ASSEMBLY FOR DUAL-MODE AIRCRAFT”, which is incorporated herein in its entirety by reference.

Still referring to FIG. 1, performance analytics 156 may include thermal data. In one embodiment, computing device 104 is further configured to calculate a probability of a thermal runaway as a function of the generated thermal datum. In one embodiment, calculating the probability of a thermal runaway includes utilizing a machine-learning process. In one embodiment, calculating thermal runaway may further include utilizing a neural network. In a non-limiting example, based on an observed increase in the battery's temperature and data from a plurality of sources, such as other observed thermal runaway events, a machine-learning module may be able to predict when a thermal runaway may occur based on the observed temperature and the environment surrounding the electric aircraft.

With continued reference to FIG. 1, performance analytics 156 may include information such as battery pack model, type, manufacturer, power levels, state of charge (SoC), depth of discharge (DoD), failure locations, gas evolution, internal heat generation, impedance, resistance, temperature levels, moisture levels, estimations of one or more battery pack healths, capacity fade, incremental capacity analysis (ICA), and the like. Performance analytics may be determined by battery model. As previously mentioned, performance analytics 156 may include information related to a current or expected condition or function of one or more battery packs and/or components thereof. For instance, and without limitation, performance analytics 156 may determine that an acceptable temperature range of a battery pack is between 70-75 degrees Fahrenheit during operation of battery pack. In some embodiments, performance analytics 156 may further include acceptable temperature range of battery pack when aircraft is executing a specific operation (e.g., when specific pilot input is received or when a specific aircraft orientation or speed is detected by sensor).

Still referring to FIG. 1, performance analytics 156 may include determined conditions or health estimation of battery pack(s) and/or components thereof. For instance, and without limitation, measurement data may include information associated with a health of a component, such as an anode or a cathode, of battery pack 108. For the purposes of this disclosure, an “anode” is a negative electrode of a power source. An anode may be composed of a metal that oxidizes and provides electrons to a corresponding cathode. The health of an anode may include quantitative or qualitative values associated with reducing agent efficiency, temperature, conductivity levels, stability, and coulombic output of anode. For the purposes of this disclosure, a “cathode” is a positive electrode of a power source that gains electrons (reduces) from an anode as the anode oxidizes. The health of a cathode may quantitative or qualitative values associated with a capacity, temperature, conductivity, energy capacity, and the like. In a non-limiting embodiment, measurement or fleet data may include a unique identification number denoting a part of an electric aircraft that was installed, repaired, or replaced as a function of an aircraft maintenance. In a non-limiting embodiment, the plurality of measured aircraft operation datum may include a record of maintenance and/or repair schedules corresponding to an electric aircraft.

Still referring to FIG. 1, performance analytics 156 may include information describing the maintenance, repair, and overhaul of an electric aircraft or an electric aircraft's flight components, such as battery pack 108. Performance analytics 156 may include a record of maintenance activities and results including, for example and without limitation, a plurality of tests, measurements, replacements, adjustments, repairs, and the like, which may be intended to retain or restore battery pack at or to a functional condition. Performance analytics 156 may include recommendations of, but not limited to, functional checks, servicing, repairing or replacing of necessary devices, equipment, machinery, and the like, pertaining to battery pack and/or electric aircraft. A “maintenance schedule,” for the purposes of this disclosure, refer to an appointment reserved for an aircraft for a maintenance or repair to be conducted upon. A person of ordinary skill in the art, after viewing the entirety of this disclosure, would appreciate the various elements of data pertaining to a record of data in the context of maintenance and repair.

Still referring to FIG. 1, in one or more embodiments, computing device may include, for example and without limitation, second node. In one or more embodiments, second node may include remote computing device. In one or more embodiments, remote computing device 144 includes a display, which is configured to display, present, indicate, and/or otherwise visually and/or verbally convey data and/or information related to measurement data, fleet data, and/or performance analytics. For example, and without limitation, display may show battery parameter and/or logistics, such as, but not limited to, temperature, health of battery pack, ambient temperatures, surface temperatures, operation of coolant systems, condition of components of battery pack, and the like. In another example, and without limitation, raw or processed information generated by computing device 104 or sensors may be shown by display. In other examples, and without limitation, information stored in and provided by a memory communicatively connected to controller or integrated into computing device 104 may be displayed on display. In various embodiments, display may be implemented with an electronic display screen and/or monitor. Exemplary embodiments of electronic display screen may include a cathode ray tube (CRT), light-emitting diode (LED), liquid-crystal display (LCD), an opaque screen, and the like. In various embodiments, display may be implemented with a projection screen and/or display. For example, and without limitation, display may include a head-up display, a projector screen, a pico-projection display, a retinal display, and the like. In one or more embodiments, display may include a monochrome or color display. Display may be suitable for presenting a user-viewable image of one or more visual representations related to generated and/or provided information discussed in this disclosure. In some embodiments, digital model 136 may be shown on an existing display of an external and/or remote device, such as a remote computing device, laptop, desktop, mobile phone, tablet, electric aircraft information display system, or any other devices that may receive flight transition information from processor, sensor, memory, a remote computing device, and the like, to present flight transition information to a user. In some embodiments, display may receive and display data and/or information converted and/or generated from computing device 104 and/or remote computing device. In other embodiments, display may receive and display collected data and/or information directly from sensor. In other embodiments, display may receive and show data and/or information stored and retrieved from memory. Data and information from memory may be transferred from memory using controller or a processor. Display may be configured to present, indicate, or otherwise convey images and or symbols, such as text, related to a flight transition of electric aircraft 112.

With continued reference to FIG. 1, performance analytics may include current and/or recommended battery parameters. For instance, and without limitation, performance analytics may include a real-time recommended range of measurement data that may be compared to a current, real-time value of battery pack. A visual representation may be used to indicate a recommended range of measurement data. Visual representation of recommended range may include a band, radially expanding circle, or portion thereof, line, and the like. In some embodiments, band may be a linear region indicated by colors or lines on display. In other embodiments, band may include an arcuate region indicated by colors and/or lines on display. Recommended range may include a lower bound and an upper bound that define the minimum and maximum limits of the range, respectively. For instance, and without limitation, lower bound may represent a lower threshold of recommended range, and upper bound may represent an upper threshold of recommended range. In some embodiments, lower and upper bound may be generated to include a safety feature, where a standard deviation of error may be included so that recommended range includes relief for user and/or environmental error.

In one or more embodiments, computing device 104 may initiate an alert as a function of performance analytics, which may be activated if a measurement data is outside of a recommended range (e.g., predetermined threshold). Alert may include one or more visual components, audio components, haptic components, instructions, and the like. For example, and without limitation, alert component may include a haptic component where a user may feel a vibration in a pilot input when a user deviates outside of recommended range or is close to deviating outside of recommended range. In another example, and without limitation, display or a light-emitting diode (LED) may flash to indicate to a user that the user is deviating from a recommended range. Haptic components may include mechanical vibrators, piezoelectric components, or other movable components for generating motion that alerts a user that a recommended range is being exceeded. Audio components may include one or more speakers. Light-emitting components may include one or more light bulbs, LEDs, at least a portion of display, and the like.

Still referring to FIG. 1, user interface may be adapted to be integrated as part of display to function as both a user input device and a display device, such as, for example, a touch screen device adapted to receive input signals from a user touching different parts of a screen of display. Processor may be configured to sense a user control input signal from user interface and respond to sensed control input signals received therefrom.

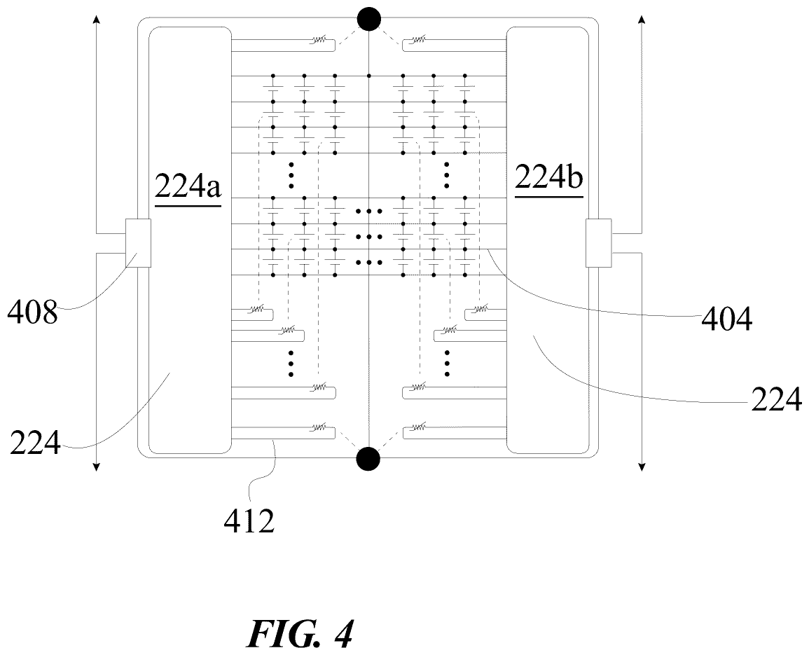

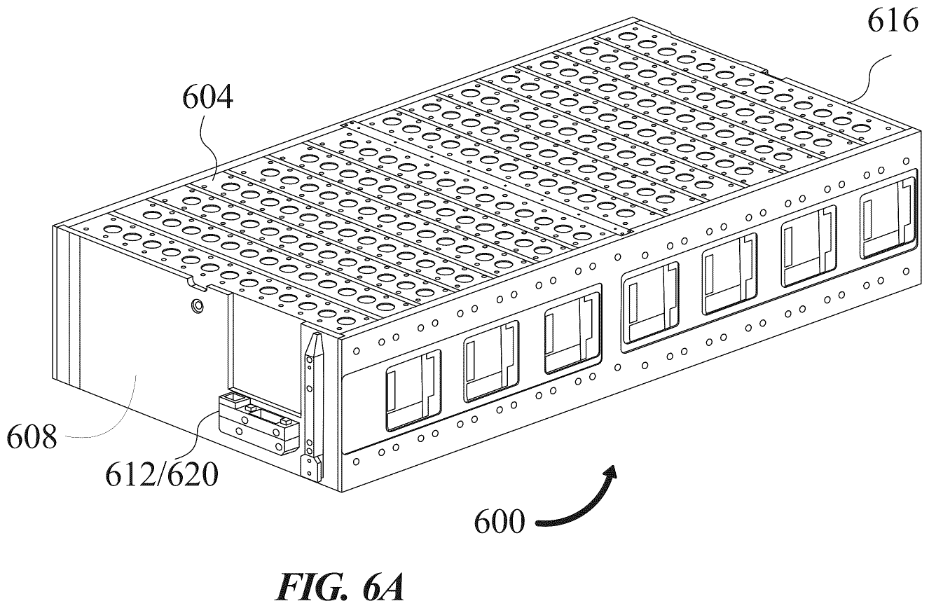

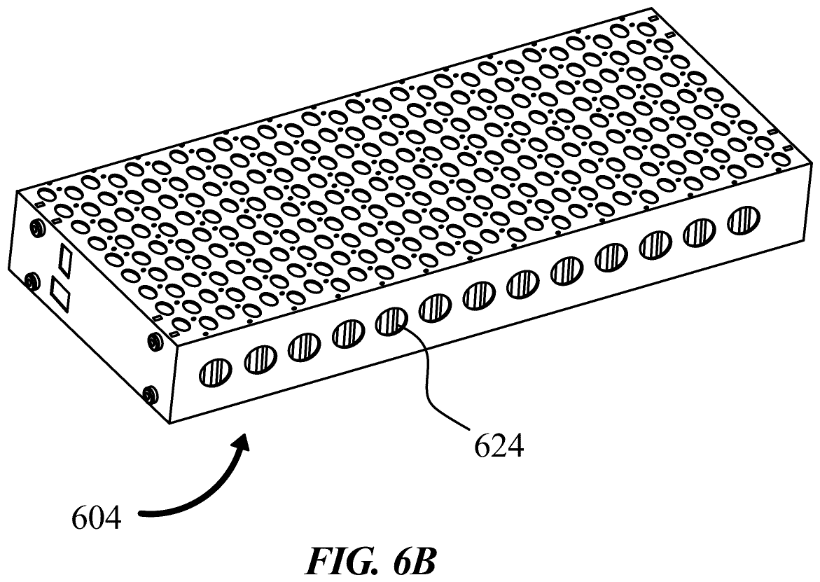

Referring now to FIG. 2, an exemplary embodiment of a battery pack 200 is presented in accordance with one or more embodiments of the present disclosure. In one or more embodiments, electric aircraft battery pack 200 (also referred to herein as a “battery pack”) includes a battery module 204, which is configured to provide energy to an electric aircraft 208 via a power supply connection 212. For the purposes of this disclosure, a “power supply connection” is an electrical and/or physical communication between a battery module 204 and electric aircraft 208 that powers electric aircraft 208 and/or electric aircraft subsystems for operation. In one or more embodiments, battery pack 200 may include a plurality of battery modules, such as modules 204a-n. For example, and without limitation, battery pack 200 may include fourteen battery modules. In one or more embodiments, each battery module 204a-n may include a battery cell 404, as shown in FIGS. 4 and 6B. For example, and without limitation, battery module 204 may include a plurality of battery cells.

Still referring to FIG. 2, battery pack 200 includes a battery management component 236 (also referred to herein as a “management component”). In one or more embodiments, battery management component 236 may be integrated into battery pack 200 in a portion of battery pack 200 or a subassembly thereof. One of ordinary skill in the art will appreciate that there are various areas in and on a battery pack and/or subassemblies thereof that may include battery management component 236. In one or more embodiments, battery management component 236 may be disposed directly over, adjacent to, facing, and/or near a battery module and specifically at least a portion of a battery cell, the arrangement of which will be disclosed with greater detail in reference to FIG. 4.

Still referring to FIG. 2, battery management component 236 includes a module monitor unit (MMU) 224, a pack monitoring unit (PMU) 228, and a high voltage disconnect 232. In one or more embodiments, battery management component 236 may also include a sensor 216. For example, and without limitation, battery management component 236 may include a sensor suite 200 (shown in FIG. 2) having a plurality of sensors. In one or more embodiments, battery management component 236 includes MMU 224, which is mechanically connected and communicatively connected to battery module 204. As used herein, “communicatively connected” is a process whereby one device, component, or circuit is able to receive data from and/or transmit data to another device, component, or circuit. In an embodiment, communicative connecting includes electrically connecting at least an output of one device, component, or circuit to at least an input of another device, component, or circuit. In one or more embodiments, MMU 224 is configured to detect a condition parameter of battery module 204 of battery pack 200. For the purposes of this disclosure, a “condition parameter” is detected electrical or physical input and/or phenomenon related to a state of a battery pack. A state of a battery pack may include detectable information related to, for example, a temperature, a moisture level, a humidity, a voltage, a current, vent gas, vibrations, chemical content, or other measurable characteristics of battery pack 200 or components thereof, such as battery module 204 and/or battery cell 304. For example, and without limitation, MMU 224 may detect and/or measure a condition parameter, such as a temperature, of battery module 204. In one or more embodiments, a condition state of battery pack 200 may include a condition state of a battery module 204 and/or battery cell 304. In one or more embodiments, MMU 224 may include a sensor, which may be configured to detect and/or measure condition parameter. As used in this disclosure, a “sensor” is a device that is configured to detect an input and/or a phenomenon and transmit information and/or datum related to the detection. A sensor may generate a sensor output signal, which transmits information and/or datum related to a sensor detection. A sensor output signal may include any signal form described in this disclosure, for example digital, analog, optical, electrical, fluidic, and the like. In some cases, a sensor, a circuit, and/or a controller may perform one or more signal processing steps on a signal. For instance, a sensor, circuit, and/or controller may analyze, modify, and/or synthesize a signal in order to improve the signal, for instance by improving transmission, storage efficiency, or signal to noise ratio. Additional disclosure related to a pack monitoring system can be found in U.S. patent application Ser. No. 17/529,447 entitled “A MODULE MONITOR UNIT FOR AN ELECTRIC AIRCRAFT BATTERY PACK AND METHODS OF USE”, entirety of which in incorporated herein by reference.

In one or more embodiments, MMU 224 is configured to transmit a measurement datum of battery module 204. MMU 224 may generate an output signal that includes a sensor output signal, such as a measurement datum, that includes information regarding detected condition parameter. For the purposes of this disclosure, “measurement datum” is an electronic signal representing information and/or datum of a detected electrical or physical characteristic and/or phenomenon correlated with a condition state of a battery pack. For example, measurement datum may include data of a condition parameter regarding a detected temperature of a battery cell. In one or more embodiments, measurement datum may be transmitted by MMU 224 to PMU 228 so that PMU 228 may receive measurement datum, as discussed further in this disclosure. For example, MMU 224 may transmit measurement data to a controller 240 of PMU 228.

In one or more embodiments, MMU 224 may include a plurality of MMUs. For instance, and without limitation, each battery module 204a-n may include one or more MMUs 224. For example, and without limitation, each battery module 204a-n may include two MMUs 224a,b. MMUs 224a,b may be positioned on opposing sides of battery module 204. Battery module 204 may include a plurality of MMUs to create redundancy so that, if one MMU fails or malfunctions, another MMU may still operate properly and continue to monitor corresponding battery module 204. In one or more non-limiting exemplary embodiments, MMU 224 may include mature technology so that there is a low risk. Furthermore, MMU 224 may not include software to, for example, increase reliability and durability of MMU 224 and thus, avoid complications often inherent with using software applications. MMU 224 is configured to monitor and balance all battery cell groups of battery pack 200 during charging of battery pack 200. For instance, and without limitation, MMU 224 may monitor a temperature of battery module 204 and/or a battery cell of battery module 204. For example, and without limitation, MMU 224 may monitor a battery cell group temperature. In another example, and without limitation, MMU 224 may monitor a terminal temperature of battery module 204 to, for example, detect a poor high voltage (HV) electrical connection. In one or more embodiments, an MMU 224 may be indirectly connected to PMU 228. In other embodiments, MMU 224 may be directly connected to PMU 228. In one or more embodiments, MMU 224 may be communicatively connected to an adjacent MMU 224.

Still referring to FIG. 2, battery management component 236 includes PMU 228, which is communicatively connected to MMU 224. In one or more embodiments, PMU 228 includes controller 240, which is configured to receive measurement datum from MMU 224. For example, PMU 228a may receive a plurality of measurement data associated with various states of a battery module 204 from MMU 224a. Similarly, PMU 228b may receive a plurality of measurement data from MMU 224b. In one or more embodiments, PMU 228 may receive measurement datum from MMU 224 via communication component, such as via communicative connections. For example, PMU 228 may receive measurement datum from MMU 224 via an isoSPI transceiver. In one or more embodiments, controller 240 of PMU 228 is configured to identify an operating condition of battery module 204 as a function of measurement datum. For the purposes of this disclosure, an “operating condition” is a state and/or working order of battery pack 200 and/or any components thereof. For example, and without limitation, an operating condition may include a state of charge (SOC), a depth of discharge (DOD), a temperature reading, a moisture/humidity level, a gas level, a chemical level, or the like. In one or more embodiments, controller 240 of PMU 228 is configured to determine a critical event element if operating condition is outside of a predetermined threshold (also referred to herein as a “threshold”). For the purposes of this disclosure, a “critical event element” is a failure and/or critical operating condition of a battery pack and/or components thereof that may be harmful to a battery pack and/or corresponding electric aircraft. For instance, and without limitation, if an identified operating condition, such as a temperature of a battery cell 304 of battery pack 200, does not fall within a predetermined threshold, such as a range of acceptable, operational temperatures of a battery cell, then a critical event element is determined by controller 240 of PMU 228. For example, and without limitation, PMU 228 may use measurement datum from MMU 224 to identify a temperature of 95° F. for a battery cell. If the predetermined temperature threshold is, for example, 75 to 90° F., then the determined operating condition is outside of the predetermined temperature threshold, such as exceeding the upper threshold of 90° F., and a critical event element is determined by controller 240. As used in this disclosure, a “predetermined threshold” is a limit and/or range of an acceptable quantitative value or representation related to a normal operating condition and/or state of a battery pack and/or components thereof. In one or more embodiments, an operating condition outside of a threshold is a critical operating condition, which triggers a critical event element. An operating condition within the threshold is a normal operating condition, which indicates that a battery pack is working properly and no critical event element is determined. For example, and without limitation, if an operating condition of temperature exceeds a predetermined temperature threshold of a battery pack, then the battery pack is considered to be operating at a critical operating condition and may be at risk of overheating and experiencing a catastrophic failure. In one or more embodiments, critical event elements may include high shock/drop, overtemperature, undervoltage, high moisture, contactor welding, and the like. Additional disclosure related to a pack monitoring system can be found in U.S. patent application Ser. No. 17/529,583 entitled “A PACK MONITORING UNIT FOR AN ELECTRIC AIRCRAFT BATTERY PACK AND METHODS OF USE FOR BATTERY MANAGEMENT”, entirety of which in incorporated herein by reference.

In one or more embodiments, controller 240 of PMU 228 is configured to generate an action command if critical event element is determined by controller 240. For the purposes of this disclosure, an “action command” is a control signal generated by a controller that provides instructions related to reparative action needed to prevent and/or reduce damage to a battery back, components thereof, and/or aircraft as a result of a critical operating condition of the battery pack. Continuing the previously described example above, if an identified operating condition includes a temperature of 95° F., which exceeds a predetermined temperature threshold, then controller 240 may determine a critical event element indicating that battery pack 200 is working at a critical temperature level and at risk of catastrophic failure.

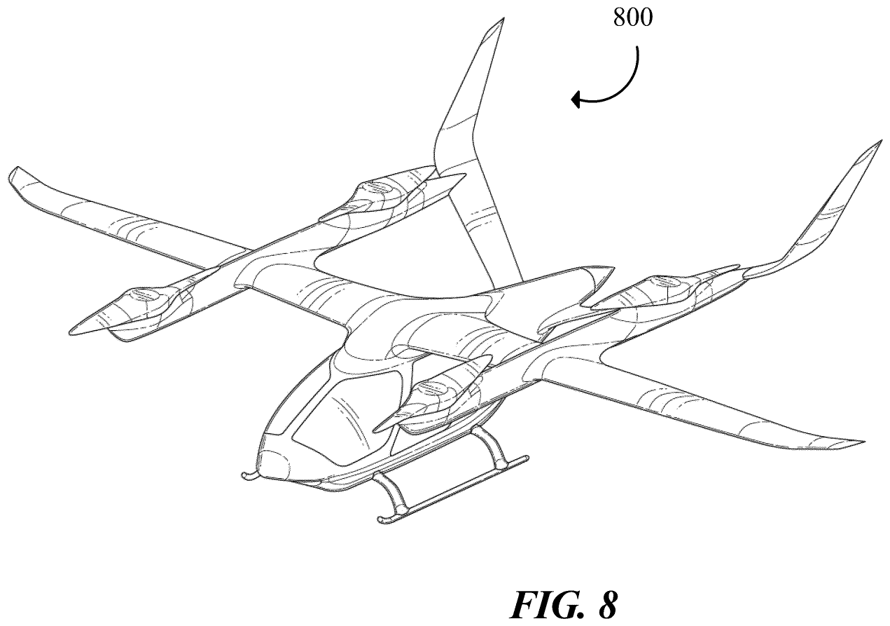

In one or more embodiments, controller 240 may include a computing device (as discussed in FIG. 8), a central processing unit (CPU), a microprocessor, a digital signal processor (DSP), an application specific integrated circuit (ASIC), a control circuit, a combination thereof, or the like. In one or more embodiments, output signals from various components of battery pack 200 may be analog or digital. Controller 240 may convert output signals from MMU 224 and/or sensor 216 to a usable form by the destination of those signals. For example, and without limitation, PMU 228 may include a switching regulator 424 that converts power received from battery module 204 of battery pack 200 (shown in FIG. 4). The usable form of output signals from MMUs and/or sensors, through processor may be either digital, analog, a combination thereof, or an otherwise unstated form. Processing may be configured to trim, offset, or otherwise compensate the outputs of sensor. Based on MMU and/or sensor output, controller 240 may determine the output to send to a downstream component. Controller 240 may include signal amplification, operational amplifier (Op-Amp), filter, digital/analog conversion, linearization circuit, current-voltage change circuits, resistance change circuits such as Wheatstone Bridge, an error compensator circuit, a combination thereof or otherwise undisclosed components. In one or more embodiments, PMU 228 may run state estimation algorithms.

Still referring to FIG. 2, battery management component 236 includes a high voltage disconnect 232 communicatively connected to battery module 204, wherein high voltage disconnect 232 is configured to terminate power supply connection 212 between battery module 204 and electric aircraft 208 in response to receiving an action command from PMU 228. PMU 228 may be configured to determine a critical event element, such as high shock/drop, overtemperature, undervoltage, contactor welding, and the like. High voltage disconnect 232 is configured to receive action command generated by PMU 228 and thus lock out battery pack 200 for maintenance in response to received action command. In one or more embodiments, PMU 228 may create an alert, such as a lockout flag, which may be saved across reboots. A “lockout flag” may include an indicator alerting a user of a critical event element and subsequent termination of power supply connection 212 by high voltage disconnect 232. In one or more embodiments, a lockout flag may be saved in memory component 244 of PMU 228 so that, despite rebooting battery pack 200 or complete loss of power of battery pack 200, power supply connection remains terminated and an alert regarding the termination remains. In one or more embodiments, an alert and/or lockout flag may be transmitted to a user device for viewing. For example, and without limitation, an alert may be shown on a mobile device, a laptop, a tablet, a display of an electric aircraft user interface, or the like. In one or more embodiments, lockout flag cannot be removed until a critical event element is no longer determined by controller 240. For, example, PMU 228 may be continuously updating an operating condition and determining if operating condition is outside of a predetermined threshold. In one or more embodiments, lockout flag may include an alert on a graphic user interface of, for example, a remote computing device, such as a mobile device, tablet, laptop, desktop and the like. In other embodiments, lockout flag may be indicated to a user via an illuminated LED that is remote or locally located on battery pack 200. In one or more embodiments, PMU 228 may include control of cell group balancing via MMUs, control of contactors (high voltage connections, etc.) control of welding detection, control of pyro fuses, and the like.

In one or more embodiments, battery management component 236 may include a plurality of PMUs 228. For instance, and without limitation, battery management component 236 may include a pair of PMUs. For example, and without limitation, battery management component 236 may include a first PMU 228a and a second PMU 228b, which are each disposed in or on battery pack 200 and may be physically isolated from each other. “Physical isolation”, for the purposes of this disclosure, refer to a first system's components, communicative connection, and any other constituent parts, whether software or hardware, are separated from a second system's components, communicative coupling, and any other constituent parts, whether software or hardware, respectively. Continuing in reference to the non-limiting exemplary embodiment, first PMU 228a and second PMU 228b may perform the same or different functions. For example, and without limitation, first and second PMUs 228a,b may perform the same, and therefore, redundant functions. Thus, if one PMU 228a/b fails or malfunctions, in whole or in part, the other PMU 228b/a may still be operating properly and therefore battery management component 236 may still operate and function properly to manage battery pack 200. One of ordinary skill in the art would understand that the terms “first” and “second” do not refer to either PMU as primary or secondary. In non-limiting embodiments, the first and second PMUs 228a,b, due to their physical isolation, may be configured to withstand malfunctions or failures in the other system and survive and operate. Provisions may be made to shield first PMU 228a from second PMU 228b other than physical location, such as structures and circuit fuses. In non-limiting embodiments, first PMU 228a, second PMU 228b, or subcomponents thereof may be disposed on an internal component or set of components within battery pack 200, such as on a battery module sense board, as discussed further below in this disclosure.

Still referring to FIG. 2, first PMU 228a may be electrically isolated from second PMU 228b. “Electrical isolation”, for the purposes of this disclosure, refer to a first system's separation of components carrying electrical signals or electrical energy from a second system's components. First PMU 228a may suffer an electrical catastrophe, rendering it inoperable, and due to electrical isolation, second PMU 228b may still continue to operate and function normally, allowing for continued management of battery pack 200 of electric aircraft 208. Shielding such as structural components, material selection, a combination thereof, or another undisclosed method of electrical isolation and insulation may be used, in non-limiting embodiments. For example, and without limitation, a rubber or other electrically insulating material component may be disposed between electrical components of first and second PMUs 228a, b, preventing electrical energy to be conducted through it, isolating the first and second PMUs 228a,b form each other. Similarly, MMUs 224 may be physically and/or electrically isolated relative to each other and/or PMUs in case of failure of an MMU and/or PMU.

With continued reference to FIG. 2, battery management component 236 may include a memory component 244. In one or more embodiments, memory component 244 may be configured to store datum related to battery pack 200, such as data related to battery modules 204a-n. For example, and without limitation, memory component 244 may store sensor datum, measurement datum, operation condition, critical event element, lockout flag, and the like. Memory component 244 may include a database. Memory component 244 may include a solid-state memory or tape hard drive. Memory component 244 may be communicatively connected to PMU 228 and may be configured to receive electrical signals related to physical or electrical phenomenon measured and store those electrical signals as battery module data. Alternatively, memory component 244 may be a plurality of discrete memory components that are physically and electrically isolated from each other. One of ordinary skill in the art would understand the virtually limitless arrangements of data stores with which battery pack 200 could employ to store battery pack data.

Referring now to FIG. 3, an embodiment of sensor suite 300 is presented. The herein disclosed system and method may comprise a plurality of sensors in the form of individual sensors or a sensor suite working in tandem or individually. A sensor suite may include a plurality of independent sensors, as described herein, where any number of the described sensors may be used to detect any number of physical or electrical quantities associated with an aircraft power system or an electrical energy storage system. Independent sensors may include separate sensors measuring physical or electrical quantities that may be powered by and/or in communication with circuits independently, where each may signal sensor output to a control circuit such as a user graphical interface. In a non-limiting example, there may be four independent sensors housed in and/or on battery pack 300 measuring temperature, electrical characteristic such as voltage, amperage, resistance, or impedance, or any other parameters and/or quantities as described in this disclosure. In an embodiment, use of a plurality of independent sensors may result in redundancy configured to employ more than one sensor that measures the same phenomenon, those sensors being of the same type, a combination of, or another type of sensor not disclosed, so that in the event one sensor fails, the ability of battery management component and/or user to detect phenomenon is maintained and in a non-limiting example, a user alter aircraft usage pursuant to sensor readings.

Sensor suite 300 may be suitable for use as sensor, such as sensor 120 as disclosed with reference to FIG. 1 hereinabove. Sensor suite 300 includes a moisture sensor 304. “Moisture”, as used in this disclosure, is the presence of water, this may include vaporized water in air, condensation on the surfaces of objects, or concentrations of liquid water. Moisture may include humidity. “Humidity”, as used in this disclosure, is the property of a gaseous medium (almost always air) to hold water in the form of vapor. An amount of water vapor contained within a parcel of air can vary significantly. Water vapor is generally invisible to the human eye and may be damaging to electrical components. There are three primary measurements of humidity, absolute, relative, specific humidity. “Absolute humidity,” for the purposes of this disclosure, describes the water content of air and is expressed in either grams per cubic meters or grams per kilogram. “Relative humidity”, for the purposes of this disclosure, is expressed as a percentage, indicating a present stat of absolute humidity relative to a maximum humidity given the same temperature. “Specific humidity”, for the purposes of this disclosure, is the ratio of water vapor mass to total moist air parcel mass, where parcel is a given portion of a gaseous medium. Moisture sensor 304 may be psychrometer. Moisture sensor 304 may be a hygrometer. Moisture sensor 304 may be configured to act as or include a humidistat. A “humidistat”, for the purposes of this disclosure, is a humidity-triggered switch, often used to control another electronic device. Moisture sensor 304 may use capacitance to measure relative humidity and include in itself, or as an external component, include a device to convert relative humidity measurements to absolute humidity measurements. “Capacitance”, for the purposes of this disclosure, is the ability of a system to store an electric charge, in this case the system is a parcel of air which may be near, adjacent to, or above a battery cell.

With continued reference to FIG. 3, sensor suite 300 may include electrical sensors 308. Electrical sensors 308 may be configured to measure voltage across a component, electrical current through a component, and resistance of a component. Electrical sensors 308 may include separate sensors to measure each of the previously disclosed electrical characteristics such as voltmeter, ammeter, and ohmmeter, respectively.

Alternatively or additionally, and with continued reference to FIG. 3, sensor suite 300 include a sensor or plurality thereof that may detect voltage and direct the charging of individual battery cells according to charge level; detection may be performed using any suitable component, set of components, and/or mechanism for direct or indirect measurement and/or detection of voltage levels, including without limitation comparators, analog to digital converters, any form of voltmeter, or the like. Sensor suite 300 and/or a control circuit incorporated therein and/or communicatively connected thereto may be configured to adjust charge to one or more battery cells as a function of a charge level and/or a detected parameter. For instance, and without limitation, sensor suite 300 may be configured to determine that a charge level of a battery cell is high based on a detected voltage level of that battery cell or portion of the battery pack. Sensor suite 300 may alternatively or additionally detect a charge reduction event, defined for purposes of this disclosure as any temporary or permanent state of a battery cell requiring reduction or cessation of charging; a charge reduction event may include a cell being fully charged and/or a cell undergoing a physical and/or electrical process that makes continued charging at a current voltage and/or current level inadvisable due to a risk that the cell will be damaged, will overheat, or the like. Detection of a charge reduction event may include detection of a temperature, of the cell above a threshold level, detection of a voltage and/or resistance level above or below a threshold, or the like. Sensor suite 300 may include digital sensors, analog sensors, or a combination thereof. Sensor suite 300 may include digital-to-analog converters (DAC), analog-to-digital converters (ADC, A/D, A-to-D), a combination thereof, or other signal conditioning components used in transmission of a first plurality of battery pack data to a destination over wireless or wired connection.

With continued reference to FIG. 3, sensor suite 300 may include thermocouples, thermistors, thermometers, passive infrared sensors, resistance temperature sensors (RTDs), semiconductor based integrated circuits (IC), a combination thereof or another undisclosed sensor type, alone or in combination. Temperature, for the purposes of this disclosure, and as would be appreciated by someone of ordinary skill in the art, is a measure of the heat energy of a system. Temperature, as measured by any number or combinations of sensors present within sensor suite 300, may be measured in Fahrenheit (° F.), Celsius (° C.), Kelvin (° K), or another scale alone or in combination. The temperature measured by sensors may comprise electrical signals which are transmitted to their appropriate destination wireless or through a wired connection.

With continued reference to FIG. 3, sensor suite 300 may include a sensor configured to detect gas that may be emitted during or after a cell failure. “Cell failure”, for the purposes of this disclosure, refers to a malfunction of a battery cell, which may be an electrochemical cell, that renders the cell inoperable for its designed function, namely providing electrical energy to at least a portion of an electric aircraft. Byproducts 312 of cell failure may include gaseous discharge including oxygen, hydrogen, carbon dioxide, methane, carbon monoxide, a combination thereof, or another undisclosed gas, alone or in combination. Further the sensor configured to detect vent gas from electrochemical cells may comprise a gas detector. For the purposes of this disclosure, a “gas detector” is a device used to detect a gas is present in an area. Gas detectors, and more specifically, the gas sensor that may be used in sensor suite 300, may be configured to detect combustible, flammable, toxic, oxygen depleted, a combination thereof, or another type of gas alone or in combination. The gas sensor that may be present in sensor suite 300 may include a combustible gas, photoionization detectors, electrochemical gas sensors, ultrasonic sensors, metal-oxide-semiconductor (MOS) sensors, infrared imaging sensors, a combination thereof, or another undisclosed type of gas sensor alone or in combination. Sensor suite 300 may include sensors that are configured to detect non-gaseous byproducts 312 of cell failure including, in non-limiting examples, liquid chemical leaks including aqueous alkaline solution, ionomer, molten phosphoric acid, liquid electrolytes with redox shuttle and ionomer, and salt water, among others. Sensor suite 300 may include sensors that are configured to detect non-gaseous byproducts 312 of cell failure including, in non-limiting examples, electrical anomalies as detected by any of the previous disclosed sensors or components.

With continued reference to FIG. 3, sensor suite 300 may be configured to detect events where voltage nears an upper voltage threshold or lower voltage threshold. The upper voltage threshold may be stored in a memory of system for comparison with an instant measurement taken by any combination of sensors present within sensor suite 300. The upper voltage threshold may be calculated and calibrated based on factors relating to battery cell health, maintenance history, location within battery pack, designed application, and type, among others. Sensor suite 300 may measure voltage at an instant, over a period of time, or periodically. Sensor suite 300 may be configured to operate at any of these detection modes, switch between modes, or simultaneous measure in more than one mode. In one or more exemplary embodiments, PMU 228, which is shown in FIG. 2, may determine, using sensor suite 300, a critical event element where voltage nears the lower voltage threshold. The lower voltage threshold may indicate power loss to or from an individual battery cell or portion of the battery pack. PMU 228 may determine through sensor suite 300 critical event elements where voltage exceeds the upper and lower voltage threshold. Events where voltage exceeds the upper and lower voltage threshold may indicate battery cell failure or electrical anomalies that could lead to potentially dangerous situations for aircraft and personnel that may be present in or near its operation.

In one or more embodiments, sensor suite 300 may include an inertial measurement unit (IMU). In one or more embodiments, an IMU may be configured to detect a change in specific force of a body. An IMU may include an accelerometer, a gyro sensor, a magnetometer, an E-compass, a G-sensor, a geomagnetic sensor, and the like. An IMU may be configured to obtain measurement datum. PMU may determine a critical event element by if, for example, an accelerometer of sensor suite 300 detects a force experienced by battery pack that exceeds a predetermined threshold.

With reference to FIG. 4, an exemplary embodiment of an MMU 224 is shown in accordance with one or more embodiments of the present disclosure. MMU 224 may monitor battery cells, such as battery cells 404. As previously mentioned, MMU 224 may include one or more sensors, such as sensor 120 or a sensor array, such as sensor suite 200. For example, MMU 224 may include a thermistor 412 to detect a temperature of a corresponding battery module 204. MMU 224 may also monitor a charging status of each battery cell 404. For example, MMU 224 may detect if one cell as more power than another cell of battery module during recharging.

Still referring to FIG. 4, as previously mentioned, battery module may include a plurality of MMUs 224. For example, battery module 204 may include a left and a right MMU on opposing sides of battery module to create redundancy, as previously discussed in this disclosure. In one or more embodiments, each MMU 224 may communicate with another MMU 224 via a communication component, such as a communicative connection. For example, an MMU 224 may communicate with an adjacent MMU 224 using an isoSPI transceiver 408. In one or more embodiments, each MMU 224 may use a wireless and/or wired connection to communicated with each other.

Still referring to FIG. 4, in one or more embodiments, MMU 224 may include one or more circuits and/or circuit elements, including and without limitation, a printed circuit board component, aligned with a first side of battery module and the openings correlating to battery cells 404. In one or more embodiments, MMU 224 may include, without limitation, a control circuit configured to perform and/or direct any actions performed by MMU 224 and/or any other component and/or element described in this disclosure; control circuit may include any analog or digital control circuit, including without limitation a combinational and/or synchronous logic circuit, a processor, microprocessor, microcontroller, or the like.

Still referring to FIG. 4, MMU 224 may include sensor 120 or sensor suite 200 configured to measure physical and/or electrical parameters, such as without limitation temperature, voltage, orientation, or the like, of one or more battery cells 504. MMU 224 and/or a control circuit incorporated therein and/or communicatively connected thereto, may further be configured to detect a measurement datum of each battery cell 404, which controller of PMU 228 may ultimately use to determine a failure within each battery cell 404, such as critical event element. Cell failure may be characterized by a spike in temperature and MMU 224 may be configured to detect that increase, which in turn, PMU 228 uses to determine a critical event element and generate signals, to disconnect power supply connection 212 and to notify users, support personnel, safety personnel, maintainers, operators, emergency personnel, aircraft computers, or a combination thereof. In one or more embodiments, measurement data of MMU may be stored in memory component 244.

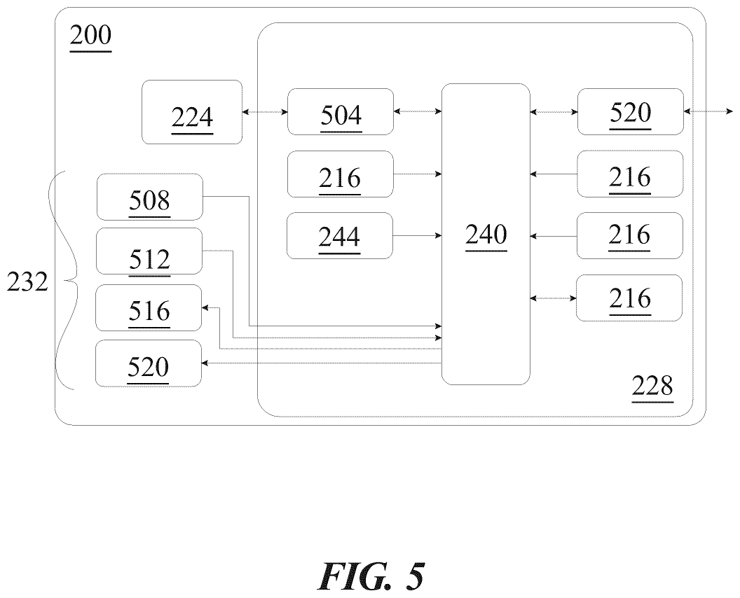

With reference to FIG. 5, an exemplary embodiment of a PMU 228 is shown in accordance with one or more embodiments of the present disclosure. In one or more embodiments, PMU 228 may include controller 240. Controller 240 may include a computing device, a processor, a microprocessor, a control circuit, control circuit, or the like. In one or more embodiments, PMU 228 may communicate with MMU 224 via a transceiver. For example, and without limitation, using an isoSPI transceiver 504.

In one or more embodiments, PMU 228 may include sensor 216. For example, and without limitation, condition characteristics of battery module may be detected by sensor 216, which may be communicatively connected to MMU 224. Sensor 216 may include a sensor suite or one or more individual sensors, which may include, but are not limited to, one or more temperature sensors, voltmeters, current sensors, hydrometers, infrared sensors, photoelectric sensors, ionization smoke sensors, motion sensors, pressure sensors, radiation sensors, level sensors, imaging devices, moisture sensors, gas and chemical sensors, flame sensors, electrical sensors, imaging sensors, force sensors, Hall sensors, airspeed sensors, throttle position sensors, and the like. Sensor 216 may be a contact or a non-contact sensor. For example, and without limitation, sensor 216 may be connected to battery module 204 and/or battery cell 404, which are shown in FIGS. 2 and 4, respectively. In other embodiments, sensor 216 may be remote to battery module and/or battery cell 404. Sensor 216 may be communicatively connected to controller 240 of PMU 228 so that sensor 216 may transmit/receive signals to/from controller 240. Signals, such as signals of sensor 216 and controller 240, may include electrical, electromagnetic, visual, audio, radio waves, or another undisclosed signal type alone or in combination. In one or more embodiments, communicatively connecting is a process whereby one device, component, or circuit is able to receive data from and/or transmit data to another device, component, or circuit. In an embodiment, communicative connecting includes electrically connecting at least an output of one device, component, or circuit to at least an input of another device, component, or circuit.

Referring still to FIG. 5, PMU 228 may include memory component 244, as previously mentioned in this disclosure. In one or more embodiments, memory component 244 may store battery pack data. Battery pack data may include be generated data, detected data, measured data, inputted data, and the like. For example, battery pack data may include measurement datum 116, which may be stored in memory component 244. In another example, critical event element and/or a corresponding lockout flag may be stored in memory component 244. Battery pack data may also include inputted datum, which may include total flight hours that battery pack and/or electric aircraft have been operating, flight plan of electric aircraft, battery pack identification, battery pack verification, a battery pack maintenance history, battery pack specifications, or the like. In one or more embodiments, battery pack maintenance history may include mechanical failures and technician resolutions thereof, electrical failures and technician resolutions thereof. Additionally, battery pack maintenance history may include component failures such that the overall battery pack still functions. In one or more embodiments, memory component 244 may be communicatively connected to sensors, such as sensor 216, that detect, measure, and obtain a plurality of measurements, which may include current, voltage, resistance, impedance, coulombs, watts, temperature, moisture/humidity, or a combination thereof. Additionally, or alternatively, memory component 244 may be communicatively connected to a sensor suite consistent with this disclosure to measure physical and/or electrical characteristics. In one or more embodiments, memory component 244 may store battery pack data that includes an upper threshold and a lower threshold of a state and/or condition consistent with this disclosure. In one or more exemplary embodiments, battery pack data may include a moisture-level threshold. The moisture-level threshold may include an absolute, relative, and/or specific moisture-level threshold. In other exemplary embodiments, battery pack data may include a temperature threshold. In other exemplary embodiments, battery pack data may include a high-shock threshold.

In one or more embodiments, memory component 244 may be configured to save measurement datum, operating condition, critical event element, and the like periodically in regular intervals to memory component 244. “Regular intervals”, for the purposes of this disclosure, refers to an event taking place repeatedly after a certain amount of elapsed time. In one or more embodiments, PMU 228 may include a timer that works in conjunction to determine regular intervals. In other embodiments, PMU may continuously update operating condition or critical event element and, thus, continuously store data related the information in memory component. A Timer may include a timing circuit, internal clock, or other circuit, component, or part configured to keep track of elapsed time and/or time of day. For example, in non-limiting embodiments, memory component 244 may save the first and second battery pack data every 40 seconds, every minute, every 30 minutes, or another time period according to timer. Additionally or alternatively, memory component 244 may save battery pack data after certain events occur, for example, in non-limiting embodiments, each power cycle, landing of the electric aircraft, when battery pack is charging or discharging, a failure oof battery module, a malfunction of battery module, a critical event element, or scheduled maintenance periods. In non-limiting embodiments, battery pack 200 phenomena may be continuously measured and stored at an intermediary storage location, and then permanently saved by memory component 244 at a later time, like at a regular interval or after an event has taken place as disclosed hereinabove. Additionally or alternatively, data storage system may be configured to save battery pack data at a predetermined time. “Predetermined time”, for the purposes of this disclosure, refers to an internal clock within battery pack commanding memory component 244 to save battery pack data at that time.

Still referring to FIG. 5, in one or more embodiments, high voltage disconnect may include a bus. A “bus”, for the purposes of this disclosure and in electrical parlance is any common connection to which any number of loads, which may be connected in parallel, and share a relatively similar voltage may be electrically coupled. Bus may be responsible for conveying electrical energy stored in battery pack 200 to at least a portion of an electric aircraft, as discussed previously in this disclosure. High voltage disconnect 232 may include a ground fault detection 508, a high voltage current sense 512, a high voltage pyro fuse 516, a high voltage contactor 520, and the like. High voltage disconnect 232 may physically and/or electrically breaks power supply communication between electric aircraft 208 and battery module 204 of battery pack 200. In one or more embodiments, in one or more embodiments, the termination of power supply connection may be restored by high voltage disconnect 232 once PMU 228 no longer determine a critical event element. In other embodiments, power supply connection may be restored manually, such as by a user.

Still referring to FIG. 5, in one or more embodiments, controller 240 may conduct reparative procedures after determining critical even element to reduce or eliminate critical element event. For example, and without limitation, controller 240 may initiate reparative procedure of a circulation of a coolant through a cooling system of battery pack 200 to lower a temperature of a battery module if the determined temperature of the battery module exceeds a predetermined temperature threshold. In another example, and without limitation, if a fluid accumulation level is detected that is then determined to exceed a predetermined byproduct threshold, then high voltage disconnect 232 may terminate power supply connection 212. According to some embodiments, a vent of battery pack 200 may be opened to circulate air through battery pack 200 and reduce detected gas levels. Additionally, vent of battery module 204 may have a vacuum applied to aid in venting of a byproduct, such as ejecta. Vacuum pressure differential may range from 0.1″Hg to 36″Hg.

Now referring to FIGS. 6A and 6B, an exemplary embodiment of an eVTOL aircraft battery pack and components thereof are illustrated. Battery pack 600 is a power source that may be configured to store electrical energy in the form of a plurality of battery modules, which themselves include of a plurality of electrochemical cells. These cells may utilize electrochemical cells, galvanic cells, electrolytic cells, fuel cells, flow cells, pouch cells, and/or voltaic cells. In general, an electrochemical cell is a device capable of generating electrical energy from chemical reactions or using electrical energy to cause chemical reactions, this disclosure will focus on the former. Voltaic or galvanic cells are electrochemical cells that generate electric current from chemical reactions, while electrolytic cells generate chemical reactions via electrolysis. In general, the term “battery” is used as a collection of cells connected in series or parallel to each other. A battery cell may, when used in conjunction with other cells, may be electrically connected in series, in parallel or a combination of series and parallel. Series connection includes wiring a first terminal of a first cell to a second terminal of a second cell and further configured to include a single conductive path for electricity to flow while maintaining the same current (measured in Amperes) through any component in the circuit. A battery cell may use the term “wired”, but one of ordinary skill in the art would appreciate that this term is synonymous with “electrically connected”, and that there are many ways to couple electrical elements like battery cells together. An example of a connector that does not include wires may be prefabricated terminals of a first gender that mate with a second terminal with a second gender. Battery cells may be wired in parallel. Parallel connection includes wiring a first and second terminal of a first battery cell to a first and second terminal of a second battery cell and further configured to include more than one conductive path for electricity to flow while maintaining the same voltage (measured in Volts) across any component in the circuit. Battery cells may be wired in a series-parallel circuit which combines characteristics of the constituent circuit types to this combination circuit. Battery cells may be electrically connected in a virtually unlimited arrangement which may confer onto the system the electrical advantages associated with that arrangement such as high-voltage applications, high-current applications, or the like. In an exemplary embodiment, and without limitation, battery pack 600 include 196 battery cells in series and 18 battery cells in parallel. This is, as someone of ordinary skill in the art would appreciate, is only an example and battery pack 600 may be configured to have a near limitless arrangement of battery cell configurations. Battery pack 600 may be designed to the Federal Aviation Administration (FAA)'s Design Assurance Level A (DAL-A), using redundant DAL-B subsystems.

With continued reference to FIG. 6A, battery pack 600 may include a plurality of battery modules 604. Battery modules 604 may be wired together in series and in parallel. Battery pack 600 may include a center sheet which may include a thin barrier. The barrier may include a fuse connecting battery modules on either side of the center sheet. The fuse may be disposed in or on the center sheet and configured to connect to an electric circuit comprising a first battery module and therefore battery unit and cells. In general, and for the purposes of this disclosure, a fuse is an electrical safety device that operate to provide overcurrent protection of an electrical circuit. As a sacrificial device, its essential component is metal wire or strip that melts when too much current flows through it, thereby interrupting energy flow. The fuse may include a thermal fuse, mechanical fuse, blade fuse, expulsion fuse, spark gap surge arrestor, varistor, or a combination thereof.

Still referring to FIG. 6A, battery pack 600 may also include a side wall that includes a laminate of a plurality of layers configured to thermally insulate the plurality of battery modules from external components of battery pack 600. The side wall layers may include materials which possess characteristics suitable for thermal insulation as described in the entirety of this disclosure like fiberglass, air, iron fibers, polystyrene foam, and thin plastic films, to name a few. The side wall may additionally or alternatively electrically insulate the plurality of battery modules from external components of battery pack 600 and the layers of which may include polyvinyl chloride (PVC), glass, asbestos, rigid laminate, varnish, resin, paper, Teflon, rubber, and menical lamina. The center sheet may be mechanically coupled to the side wall in any manner described in the entirety of this disclosure or otherwise undisclosed methods, alone or in combination. The side wall may include a feature for alignment and coupling to the center sheet. This feature may include a cutout, slots, holes, bosses, ridges, channels, and/or other undisclosed mechanical features, alone or in combination.

With continued reference to FIG. 6A, battery pack 600 may also include an end panel 608 including a plurality of electrical connectors and further configured to fix battery pack 600 in alignment with at least the side wall. End panel 608 may include a plurality of electrical connectors of a first gender configured to electrically and mechanically connect to electrical connectors of a second gender. The end panel may be configured to convey electrical energy from battery cells to at least a portion of an eVTOL aircraft, for example, using high voltage disconnect 612. Electrical energy may be configured to power at least a portion of an eVTOL aircraft or include signals to notify aircraft computers, personnel, users, pilots, and any others of information regarding battery health, emergencies, and/or electrical characteristics. The plurality of electrical connectors may include blind mate connectors, plug and socket connectors, screw terminals, ring and spade connectors, blade connectors, and/or an undisclosed type alone or in combination. The electrical connectors of which the end panel includes may be configured for power and communication purposes. A first end of the end panel may be configured to mechanically couple to a first end of a first side wall by a snap attachment mechanism, similar to end cap and side panel configuration utilized in the battery module. To reiterate, a protrusion disposed in or on the end panel may be captured, at least in part, by a receptacle disposed in or on the side wall. A second end of end the panel may be mechanically coupled to a second end of a second side wall in a similar or the same mechanism.

With continued reference to FIG. 6A, sensor suite may be disposed in or on a portion of battery pack 600 near battery modules or battery cells. In one or more embodiments, PMU may be configured to communicate with an electric aircraft, such as a flight controller of electric aircraft, using a controller area network (CAN), such as by using a CAN transceiver 616. In one or more embodiments, a controller area network may include a bus. Bus may include an electrical bus. Bus may refer to power busses, audio busses, video busses, computing address busses, and/or data busses. Bus may be additionally or alternatively responsible for conveying electrical signals generated by any number of components within battery pack 600 to any destination on or offboard an electric aircraft. Battery management component 620 may include wiring or conductive surfaces only in portions required to electrically couple bus to electrical power or necessary circuits to convey that power or signals to their destinations.

Still referring to FIG. 6A, outputs from sensors or any other component present within system may be analog or digital. Onboard or remotely located processors can convert those output signals from sensor suite to a usable form by the destination of those signals. The usable form of output signals from sensors, through processor may be either digital, analog, a combination thereof or an otherwise unstated form. Processing may be configured to trim, offset, or otherwise compensate the outputs of sensor suite. Based on sensor output, the processor can determine the output to send to downstream component. Processor can include signal amplification, operational amplifier (Op-Amp), filter, digital/analog conversion, linearization circuit, current-voltage change circuits, resistance change circuits such as Wheatstone Bridge, an error compensator circuit, a combination thereof or otherwise undisclosed components.

With reference to FIG. 6B, any of the disclosed components or systems, namely battery pack 600, battery management component 620, battery module 604, and/or battery cell 624 may incorporate provisions to dissipate heat energy present due to electrical resistance in integral circuit. Battery pack 600 includes one or more battery element modules wired in series and/or parallel. The presence of a voltage difference and associated amperage inevitably will increase heat energy present in and around battery pack 600 as a whole. The presence of heat energy in a power system is potentially dangerous by introducing energy possibly sufficient to damage mechanical, electrical, and/or other systems present in at least a portion of an electric aircraft. Battery pack 600 may include mechanical design elements, one of ordinary skill in the art, may thermodynamically dissipate heat energy away from battery pack 600. The mechanical design may include, but is not limited to, slots, fins, heat sinks, perforations, a combination thereof, or another undisclosed element.

With continued reference to FIG. 6A, heat dissipation may include material selection beneficial to move heat energy in a suitable manner for operation of battery pack 600. Certain materials with specific atomic structures and therefore specific elemental or alloyed properties and characteristics may be selected in construction of battery pack 600 to transfer heat energy out of a vulnerable location or selected to withstand certain levels of heat energy output that may potentially damage an otherwise unprotected component. One of ordinary skill in the art, after reading the entirety of this disclosure would understand that material selection may include titanium, steel alloys, nickel, copper, nickel-copper alloys such as Monel, tantalum and tantalum alloys, tungsten and tungsten alloys such as Inconel, a combination thereof, or another undisclosed material or combination thereof. Heat dissipation may include a combination of mechanical design and material selection. The responsibility of heat dissipation may fall upon the material selection and design as disclosed above in regard to any component disclosed in this paper. The battery pack 600 may include similar or identical features and materials ascribed to battery pack 600 in order to manage the heat energy produced by these systems and components.

With continued reference to FIG. 6A, according to embodiments, the circuitry disposed within or on battery pack 600 may be shielded from electromagnetic interference. The battery elements and associated circuitry may be shielded by material such as mylar, aluminum, copper a combination thereof, or another suitable material. The battery pack 600 and associated circuitry may include one or more of the aforementioned materials in their inherent construction or additionally added after manufacture for the express purpose of shielding a vulnerable component. The battery pack 600 and associated circuitry may alternatively or additionally be shielded by location. Electrochemical interference shielding by location includes a design configured to separate a potentially vulnerable component from energy that may compromise the function of said component. The location of vulnerable component may be a physical uninterrupted distance away from an interfering energy source, or location configured to include a shielding element between energy source and target component. The shielding may include an aforementioned material in this section, a mechanical design configured to dissipate the interfering energy, and/or a combination thereof. The shielding comprising material, location and additional shielding elements may defend a vulnerable component from one or more types of energy at a single time and instance or include separate shielding for individual potentially interfering energies.

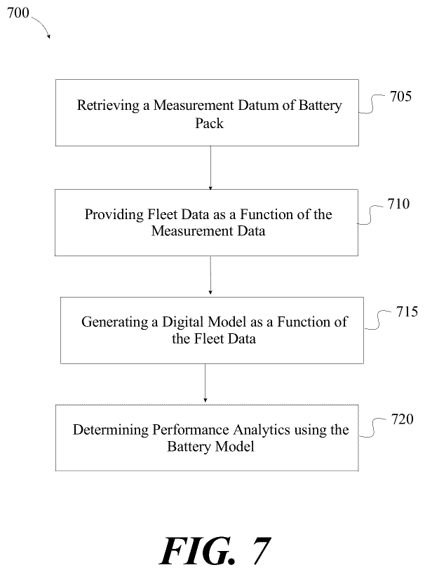

Referring now to FIG. 7, a flow chart showing an exemplary method 700 of apparatus 100 in accordance with one or more embodiments of the present disclosure. As shown in step 705, method 700 includes retrieving measurement data associated with one or more battery packs of an electric aircraft. This may be implemented as disclosed with reference to FIGS. 1-6, above. In one or more embodiments, method 700 includes transmitting measurement data to one or more nodes described in this disclosure. In one or more embodiments, node may include a second node, a third node, or a fourth node, as described previously in this disclosure. In some embodiments, transmitting measurement data may include transmitting measurement datum using a communicative connection, such as a wireless or wired connection. In other embodiments, transmitting measurement data may include transmitting measurement data using a charging connection. This may be implemented as disclosed with reference to FIGS. 1-6, above.

As shown in step 710, method 700 providing fleet data as a function of measurement data. This may be implemented as disclosed with reference to FIGS. 1-6, above.

As shown in step block 715, method 700 includes generating a battery model as a function of the fleet data and/or measurement data. This may be implemented as disclosed with reference to FIGS. 1-6 above, Battery model may include a machine-learning model as described in this disclosure. In one or more embodiments, battery model may generate a lookup table, which may provide outputs to various inputs of battery characteristics.

As shown in step 720, method 700 includes determining performance analytics using battery model. In one or more embodiments, battery model may generate a lookup table. Lookup table may allow a computing device to receive current measurement or fleet data of a battery pack and determine performance analytics of battery pack. This may be implemented as disclosed with reference to FIGS. 1-6 above.

Referring now to FIG. 8, an embodiment of an electric aircraft 800 is presented in accordance with one or more embodiments of the present disclosure. Electric aircraft 800 may include a vertical takeoff and landing aircraft (eVTOL). As used herein, a vertical take-off and landing (eVTOL) aircraft is one that can hover, take off, and land vertically. An eVTOL, as used herein, is an electrically powered aircraft typically using an energy source, of a plurality of energy sources to power the aircraft. In order to optimize the power and energy necessary to propel the aircraft. eVTOL may be capable of rotor-based cruising flight, rotor-based takeoff, rotor-based landing, fixed-wing cruising flight, airplane-style takeoff, airplane-style landing, and/or any combination thereof. Rotor-based flight, as described herein, is where the aircraft generated lift and propulsion by way of one or more powered rotors coupled with an engine, such as a “quad copter,” multi-rotor helicopter, or other vehicle that maintains its lift primarily using downward thrusting propulsors. Fixed-wing flight, as described herein, is where the aircraft is capable of flight using wings and/or foils that generate life caused by the aircraft's forward airspeed and the shape of the wings and/or foils, such as airplane-style flight.

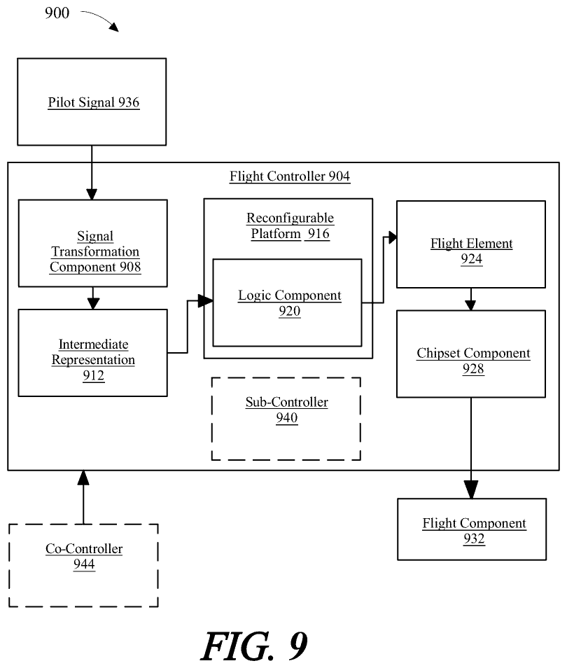

Now referring to FIG. 9 an exemplary embodiment of a flight controller 900 is shown in accordance with one or more embodiments of the present disclosure. As used in this disclosure a “flight controller” is a computing device of a plurality of computing devices dedicated to data storage, security, distribution of traffic for load balancing, and flight instruction. Flight controller 404 may include and/or communicate with any computing device as described in this disclosure, including without limitation a microcontroller, microprocessor, digital signal processor (DSP) and/or system on a chip (SoC) as described in this disclosure. Further, flight controller 904 may include a single computing device operating independently, or may include two or more computing device operating in concert, in parallel, sequentially or the like; two or more computing devices may be included together in a single computing device or in two or more computing devices. In embodiments, flight controller 904 may be installed in an aircraft, may control the aircraft remotely, and/or may include an element installed in the aircraft and a remote element in communication therewith. In some embodiments, flight controller 904 may be configured to generate a node as described in FIG. 1.

In an embodiment, and still referring to FIG. 9, flight controller 904 may include a signal transformation component 908. As used in this disclosure a “signal transformation component” is a component that transforms and/or converts a first signal to a second signal, wherein a signal may include one or more digital and/or analog signals. For example, and without limitation, signal transformation component 908 may be configured to perform one or more operations such as preprocessing, lexical analysis, parsing, semantic analysis, and the like thereof. In an embodiment, and without limitation, signal transformation component 908 may include one or more analog-to-digital convertors that transform a first signal of an analog signal to a second signal of a digital signal. For example, and without limitation, an analog-to-digital converter may convert an analog input signal to a 10-bit binary digital representation of that signal. In another embodiment, signal transformation component 908 may include transforming one or more low-level languages such as, but not limited to, machine languages and/or assembly languages. For example, and without limitation, signal transformation component 908 may include transforming a binary language signal to an assembly language signal. In an embodiment, and without limitation, signal transformation component 908 may include transforming one or more high-level languages and/or formal languages such as but not limited to alphabets, strings, and/or languages. For example, and without limitation, high-level languages may include one or more system languages, scripting languages, domain-specific languages, visual languages, esoteric languages, and the like thereof. As a further non-limiting example, high-level languages may include one or more algebraic formula languages, business data languages, string and list languages, object-oriented languages, and the like thereof.

Still referring to FIG. 9, signal transformation component 908 may be configured to optimize an intermediate representation 912. As used in this disclosure an “intermediate representation” is a data structure and/or code that represents the input signal. Signal transformation component 908 may optimize intermediate representation as a function of a data-flow analysis, dependence analysis, alias analysis, pointer analysis, escape analysis, and the like thereof. In an embodiment, and without limitation, signal transformation component 908 may optimize intermediate representation 912 as a function of one or more inline expansions, dead code eliminations, constant propagation, loop transformations, and/or automatic parallelization functions. In another embodiment, signal transformation component 908 may optimize intermediate representation as a function of a machine dependent optimization such as a peephole optimization, wherein a peephole optimization may rewrite short sequences of code into more efficient sequences of code. Signal transformation component 908 may optimize intermediate representation to generate an output language, wherein an “output language,” as used herein, is the native machine language of flight controller 904. For example, and without limitation, native machine language may include one or more binary and/or numerical languages.

In an embodiment, and without limitation, signal transformation component 908 may include transform one or more inputs and outputs as a function of an error correction code. An error correction code, also known as error correcting code (ECC), is an encoding of a message or lot of data using redundant information, permitting recovery of corrupted data. An ECC may include a block code, in which information is encoded on fixed-size packets and/or blocks of data elements such as symbols of predetermined size, bits, or the like. Reed-Solomon coding, in which message symbols within a symbol set having q symbols are encoded as coefficients of a polynomial of degree less than or equal to a natural number k, over a finite field F with q elements; strings so encoded have a minimum hamming distance of k+1, and permit correction of (q−k−1)/2 erroneous symbols. Block code may alternatively or additionally be implemented using Golay coding, also known as binary Golay coding, Bose-Chaudhuri, Hocquenghuem (BCH) coding, multidimensional parity-check coding, and/or Hamming codes. An ECC may alternatively or additionally be based on a convolutional code.

In an embodiment, and still referring to FIG. 9, flight controller 904 may include a reconfigurable hardware platform 916. A “reconfigurable hardware platform,” as used herein, is a component and/or unit of hardware that may be reprogrammed, such that, for instance, a data path between elements such as logic gates or other digital circuit elements may be modified to change an algorithm, state, logical sequence, or the like of the component and/or unit. This may be accomplished with such flexible high-speed computing fabrics as field-programmable gate arrays (FPGAs), which may include a grid of interconnected logic gates, connections between which may be severed and/or restored to program in modified logic. Reconfigurable hardware platform 916 may be reconfigured to enact any algorithm and/or algorithm selection process received from another computing device and/or created using machine-learning processes.

Still referring to FIG. 9, reconfigurable hardware platform 916 may include a logic component 920. As used in this disclosure a “logic component” is a component that executes instructions on output language. For example, and without limitation, logic component may perform basic arithmetic, logic, controlling, input/output operations, and the like thereof. Logic component 920 may include any suitable processor, such as without limitation a component incorporating logical circuitry for performing arithmetic and logical operations, such as an arithmetic and logic unit (ALU), which may be regulated with a state machine and directed by operational inputs from memory and/or sensors; logic component 920 may be organized according to Von Neumann and/or Harvard architecture as a non-limiting example. Logic component 920 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC). In an embodiment, logic component 920 may include one or more integrated circuit microprocessors, which may contain one or more central processing units, central processors, and/or main processors, on a single metal-oxide-semiconductor chip. Logic component 920 may be configured to execute a sequence of stored instructions to be performed on the output language and/or intermediate representation 912. Logic component 920 may be configured to fetch and/or retrieve the instruction from a memory cache, wherein a “memory cache,” as used in this disclosure, is a stored instruction set on flight controller 904. Logic component 920 may be configured to decode the instruction retrieved from the memory cache to opcodes and/or operands. Logic component 920 may be configured to execute the instruction on intermediate representation 912 and/or output language. For example, and without limitation, logic component 920 may be configured to execute an addition operation on intermediate representation 912 and/or output language.

In an embodiment, and without limitation, logic component 920 may be configured to calculate a flight element 924. As used in this disclosure a “flight element” is an element of datum denoting a relative status of aircraft. For example, and without limitation, flight element 924 may denote one or more torques, thrusts, airspeed velocities, forces, altitudes, groundspeed velocities, directions during flight, directions facing, forces, orientations, and the like thereof. For example, and without limitation, flight element 924 may denote that aircraft is cruising at an altitude and/or with a sufficient magnitude of forward thrust. As a further non-limiting example, flight status may denote that is building thrust and/or groundspeed velocity in preparation for a takeoff. As a further non-limiting example, flight element 924 may denote that aircraft is following a flight path accurately and/or sufficiently.

Still referring to FIG. 9, flight controller 904 may include a chipset component 928. As used in this disclosure a “chipset component” is a component that manages data flow. In an embodiment, and without limitation, chipset component 928 may include a northbridge data flow path, wherein the northbridge dataflow path may manage data flow from logic component 920 to a high-speed device and/or component, such as a RAM, graphics controller, and the like thereof. In another embodiment, and without limitation, chipset component 928 may include a southbridge data flow path, wherein the southbridge dataflow path may manage data flow from logic component 920 to lower-speed peripheral buses, such as a peripheral component interconnect (PCI), industry standard architecture (ICA), and the like thereof. In an embodiment, and without limitation, southbridge data flow path may include managing data flow between peripheral connections such as ethernet, USB, audio devices, and the like thereof. Additionally or alternatively, chipset component 928 may manage data flow between logic component 920, memory cache, and a flight component 932. As used in this disclosure a “flight component” is a portion of an aircraft that can be moved or adjusted to affect one or more flight elements. For example, flight component 932 may include a component used to affect the aircrafts' roll and pitch which may comprise one or more ailerons. As a further example, flight component 932 may include a rudder to control yaw of an aircraft. In an embodiment, chipset component 928 may be configured to communicate with a plurality of flight components as a function of flight element 924. For example, and without limitation, chipset component 928 may transmit to an aircraft rotor to reduce torque of a first lift propulsor and increase the forward thrust produced by a pusher component to perform a flight maneuver.

In an embodiment, and still referring to FIG. 9, flight controller 904 may be configured generate an autonomous function. As used in this disclosure an “autonomous function” is a mode and/or function of flight controller 904 that controls aircraft automatically. For example, and without limitation, autonomous function may perform one or more aircraft maneuvers, take offs, landings, altitude adjustments, flight leveling adjustments, turns, climbs, and/or descents. As a further non-limiting example, autonomous function may adjust one or more airspeed velocities, thrusts, torques, and/or groundspeed velocities. As a further non-limiting example, autonomous function may perform one or more flight path corrections and/or flight path modifications as a function of flight element 924. In an embodiment, autonomous function may include one or more modes of autonomy such as, but not limited to, autonomous mode, semi-autonomous mode, and/or non-autonomous mode. As used in this disclosure “autonomous mode” is a mode that automatically adjusts and/or controls aircraft and/or the maneuvers of aircraft in its entirety. For example, autonomous mode may denote that flight controller 904 will adjust the aircraft. As used in this disclosure a “semi-autonomous mode” is a mode that automatically adjusts and/or controls a portion and/or section of aircraft. For example, and without limitation, semi-autonomous mode may denote that a pilot will control the propulsors, wherein flight controller 904 will control the ailerons and/or rudders. As used in this disclosure “non-autonomous mode” is a mode that denotes a pilot will control aircraft and/or maneuvers of aircraft in its entirety.

In an embodiment, and still referring to FIG. 9, flight controller 904 may generate autonomous function as a function of an autonomous machine-learning model. As used in this disclosure an “autonomous machine-learning model” is a machine-learning model to produce an autonomous function output given flight element 924 and a pilot signal 936 as inputs; this is in contrast to a non-machine learning software program where the commands to be executed are determined in advance by a user and written in a programming language. As used in this disclosure a “pilot signal” is an element of datum representing one or more functions a pilot is controlling and/or adjusting. For example, pilot signal 936 may denote that a pilot is controlling and/or maneuvering ailerons, wherein the pilot is not in control of the rudders and/or propulsors. In an embodiment, pilot signal 936 may include an implicit signal and/or an explicit signal. For example, and without limitation, pilot signal 936 may include an explicit signal, wherein the pilot explicitly states there is a lack of control and/or desire for autonomous function. As a further non-limiting example, pilot signal 936 may include an explicit signal directing flight controller 904 to control and/or maintain a portion of aircraft, a portion of the flight plan, the entire aircraft, and/or the entire flight plan. As a further non-limiting example, pilot signal 936 may include an implicit signal, wherein flight controller 904 detects a lack of control such as by a malfunction, torque alteration, flight path deviation, and the like thereof. In an embodiment, and without limitation, pilot signal 936 may include one or more explicit signals to reduce torque, and/or one or more implicit signals that torque may be reduced due to reduction of airspeed velocity. In an embodiment, and without limitation, pilot signal 936 may include one or more local and/or global signals. For example, and without limitation, pilot signal 936 may include a local signal that is transmitted by a pilot and/or crew member. As a further non-limiting example, pilot signal 936 may include a global signal that is transmitted by air traffic control and/or one or more remote users that are in communication with the pilot of aircraft. In an embodiment, pilot signal 936 may be received as a function of a tri-state bus and/or multiplexor that denotes an explicit pilot signal should be transmitted prior to any implicit or global pilot signal.

Still referring to FIG. 9, autonomous machine-learning model may include one or more autonomous machine-learning processes such as supervised, unsupervised, or reinforcement machine-learning processes that flight controller 904 and/or a remote device may or may not use in the generation of autonomous function. As used in this disclosure “remote device” is an external device to flight controller 904. Additionally or alternatively, autonomous machine-learning model may include one or more autonomous machine-learning processes that a field-programmable gate array (FPGA) may or may not use in the generation of autonomous function. Autonomous machine-learning process may include, without limitation machine learning processes such as simple linear regression, multiple linear regression, polynomial regression, support vector regression, ridge regression, lasso regression, elasticnet regression, decision tree regression, random forest regression, logistic regression, logistic classification, K-nearest neighbors, support vector machines, kernel support vector machines, naïve bayes, decision tree classification, random forest classification, K-means clustering, hierarchical clustering, dimensionality reduction, principal component analysis, linear discriminant analysis, kernel principal component analysis, Q-learning, State Action Reward State Action (SARSA), Deep-Q network, Markov decision processes, Deep Deterministic Policy Gradient (DDPG), or the like thereof.

In an embodiment, and still referring to FIG. 9, autonomous machine learning model may be trained as a function of autonomous training data, wherein autonomous training data may correlate a flight element, pilot signal, and/or simulation data to an autonomous function. For example, and without limitation, a flight element of an airspeed velocity, a pilot signal of limited and/or no control of propulsors, and a simulation data of required airspeed velocity to reach the destination may result in an autonomous function that includes a semi-autonomous mode to increase thrust of the propulsors. Autonomous training data may be received as a function of user-entered valuations of flight elements, pilot signals, simulation data, and/or autonomous functions. Flight controller 904 may receive autonomous training data by receiving correlations of flight element, pilot signal, and/or simulation data to an autonomous function that were previously received and/or determined during a previous iteration of generation of autonomous function. Autonomous training data may be received by one or more remote devices and/or FPGAs that at least correlate a flight element, pilot signal, and/or simulation data to an autonomous function. Autonomous training data may be received in the form of one or more user-entered correlations of a flight element, pilot signal, and/or simulation data to an autonomous function.

Still referring to FIG. 9, flight controller 904 may receive autonomous machine-learning model from a remote device and/or FPGA that utilizes one or more autonomous machine learning processes, wherein a remote device and an FPGA is described above in detail. For example, and without limitation, a remote device may include a computing device, external device, processor, FPGA, microprocessor and the like thereof. Remote device and/or FPGA may perform the autonomous machine-learning process using autonomous training data to generate autonomous function and transmit the output to flight controller 904. Remote device and/or FPGA may transmit a signal, bit, datum, or parameter to flight controller 904 that at least relates to autonomous function. Additionally or alternatively, the remote device and/or FPGA may provide an updated machine-learning model. For example, and without limitation, an updated machine-learning model may be comprised of a firmware update, a software update, a autonomous machine-learning process correction, and the like thereof. As a non-limiting example a software update may incorporate a new simulation data that relates to a modified flight element. Additionally or alternatively, the updated machine learning model may be transmitted to the remote device and/or FPGA, wherein the remote device and/or FPGA may replace the autonomous machine-learning model with the updated machine-learning model and generate the autonomous function as a function of the flight element, pilot signal, and/or simulation data using the updated machine-learning model. The updated machine-learning model may be transmitted by the remote device and/or FPGA and received by flight controller 904 as a software update, firmware update, or corrected autonomous machine-learning model. For example, and without limitation autonomous machine learning model may utilize a neural net machine-learning process, wherein the updated machine-learning model may incorporate a gradient boosting machine-learning process.

Still referring to FIG. 9, flight controller 904 may include, be included in, and/or communicate with a mobile device such as a mobile telephone or smartphone. Further, flight controller may communicate with one or more additional devices as described below in further detail via a network interface device. The network interface device may be utilized for commutatively connecting a flight controller to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. The network may include any network topology and can may employ a wired and/or a wireless mode of communication.

In an embodiment, and still referring to FIG. 9, flight controller 904 may include, but is not limited to, for example, a cluster of flight controllers in a first location and a second flight controller or cluster of flight controllers in a second location. Flight controller 904 may include one or more flight controllers dedicated to data storage, security, distribution of traffic for load balancing, and the like. Flight controller 904 may be configured to distribute one or more computing tasks as described below across a plurality of flight controllers, which may operate in parallel, in series, redundantly, or in any other manner used for distribution of tasks or memory between computing devices. For example, and without limitation, flight controller 904 may implement a control algorithm to distribute and/or command the plurality of flight controllers. As used in this disclosure a “control algorithm” is a finite sequence of well-defined computer implementable instructions that may determine the flight component of the plurality of flight components to be adjusted. For example, and without limitation, control algorithm may include one or more algorithms that reduce and/or prevent aviation asymmetry. As a further non-limiting example, control algorithms may include one or more models generated as a function of a software including, but not limited to Simulink by MathWorks, Natick, Massachusetts, USA. In an embodiment, and without limitation, control algorithm may be configured to generate an auto-code, wherein an “auto-code,” is used herein, is a code and/or algorithm that is generated as a function of the one or more models and/or software's. In another embodiment, control algorithm may be configured to produce a segmented control algorithm. As used in this disclosure a “segmented control algorithm” is control algorithm that has been separated and/or parsed into discrete sections. For example, and without limitation, segmented control algorithm may parse control algorithm into two or more segments, wherein each segment of control algorithm may be performed by one or more flight controllers operating on distinct flight components.

In an embodiment, and still referring to FIG. 9, control algorithm may be configured to determine a segmentation boundary as a function of segmented control algorithm. As used in this disclosure a “segmentation boundary” is a limit and/or delineation associated with the segments of the segmented control algorithm. For example, and without limitation, segmentation boundary may denote that a segment in the control algorithm has a first starting section and/or a first ending section. As a further non-limiting example, segmentation boundary may include one or more boundaries associated with an ability of flight component 932. In an embodiment, control algorithm may be configured to create an optimized signal communication as a function of segmentation boundary. For example, and without limitation, optimized signal communication may include identifying the discrete timing required to transmit and/or receive the one or more segmentation boundaries. In an embodiment, and without limitation, creating optimized signal communication further comprises separating a plurality of signal codes across the plurality of flight controllers. For example, and without limitation the plurality of flight controllers may include one or more formal networks, wherein formal networks transmit data along an authority chain and/or are limited to task-related communications. As a further non-limiting example, communication network may include informal networks, wherein informal networks transmit data in any direction. In an embodiment, and without limitation, the plurality of flight controllers may include a chain path, wherein a “chain path,” as used herein, is a linear communication path comprising a hierarchy that data may flow through. In an embodiment, and without limitation, the plurality of flight controllers may include an all-channel path, wherein an “all-channel path,” as used herein, is a communication path that is not restricted to a particular direction. For example, and without limitation, data may be transmitted upward, downward, laterally, and the like thereof. In an embodiment, and without limitation, the plurality of flight controllers may include one or more neural networks that assign a weighted value to a transmitted datum. For example, and without limitation, a weighted value may be assigned as a function of one or more signals denoting that a flight component is malfunctioning and/or in a failure state.

Still referring to FIG. 9, the plurality of flight controllers may include a master bus controller. As used in this disclosure a “master bus controller” is one or more devices and/or components that are connected to a bus to initiate a direct memory access transaction, wherein a bus is one or more terminals in a bus architecture. Master bus controller may communicate using synchronous and/or asynchronous bus control protocols. In an embodiment, master bus controller may include flight controller 904. In another embodiment, master bus controller may include one or more universal asynchronous receiver-transmitters (UART). For example, and without limitation, master bus controller may include one or more bus architectures that allow a bus to initiate a direct memory access transaction from one or more buses in the bus architectures. As a further non-limiting example, master bus controller may include one or more peripheral devices and/or components to communicate with another peripheral device and/or component and/or the master bus controller. In an embodiment, master bus controller may be configured to perform bus arbitration. As used in this disclosure “bus arbitration” is method and/or scheme to prevent multiple buses from attempting to communicate with and/or connect to master bus controller. For example and without limitation, bus arbitration may include one or more schemes such as a small computer interface system, wherein a small computer interface system is a set of standards for physical connecting and transferring data between peripheral devices and master bus controller by defining commands, protocols, electrical, optical, and/or logical interfaces. In an embodiment, master bus controller may receive intermediate representation 912 and/or output language from logic component 920, wherein output language may include one or more analog-to-digital conversions, low bit rate transmissions, message encryptions, digital signals, binary signals, logic signals, analog signals, and the like thereof described above in detail.

Still referring to FIG. 9, master bus controller may communicate with a slave bus. As used in this disclosure a “slave bus” is one or more peripheral devices and/or components that initiate a bus transfer. For example, and without limitation, slave bus may receive one or more controls and/or asymmetric communications from master bus controller, wherein slave bus transfers data stored to master bus controller. In an embodiment, and without limitation, slave bus may include one or more internal buses, such as but not limited to a/an internal data bus, memory bus, system bus, front-side bus, and the like thereof. In another embodiment, and without limitation, slave bus may include one or more external buses such as external flight controllers, external computers, remote devices, printers, aircraft computer systems, flight control systems, and the like thereof.

In an embodiment, and still referring to FIG. 9, control algorithm may optimize signal communication as a function of determining one or more discrete timings. For example, and without limitation master bus controller may synchronize timing of the segmented control algorithm by injecting high priority timing signals on a bus of the master bus control. As used in this disclosure a “high priority timing signal” is information denoting that the information is important. For example, and without limitation, high priority timing signal may denote that a section of control algorithm is of high priority and should be analyzed and/or transmitted prior to any other sections being analyzed and/or transmitted. In an embodiment, high priority timing signal may include one or more priority packets. As used in this disclosure a “priority packet” is a formatted unit of data that is communicated between the plurality of flight controllers. For example, and without limitation, priority packet may denote that a section of control algorithm should be used and/or is of greater priority than other sections.

Still referring to FIG. 9, flight controller 904 may also be implemented using a “shared nothing” architecture in which data is cached at the worker, in an embodiment, this may enable scalability of aircraft and/or computing device. Flight controller 904 may include a distributer flight controller. As used in this disclosure a “distributer flight controller” is a component that adjusts and/or controls a plurality of flight components as a function of a plurality of flight controllers. For example, distributer flight controller may include a flight controller that communicates with a plurality of additional flight controllers and/or clusters of flight controllers. In an embodiment, distributed flight control may include one or more neural networks. For example, neural network also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes, one or more intermediate layers, and an output layer of nodes. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 9, a node may include, without limitation a plurality of inputs xᵢ that may receive numerical values from inputs to a neural network containing the node and/or from other nodes. Node may perform a weighted sum of inputs using weights wᵢ that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight wᵢ applied to an input xᵢ may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above. In an embodiment, and without limitation, a neural network may receive semantic units as inputs and output vectors representing such semantic units according to weights wᵢ that are derived using machine-learning processes as described in this disclosure.

Still referring to FIG. 9, flight controller may include a sub-controller 940. As used in this disclosure a “sub-controller” is a controller and/or component that is part of a distributed controller as described above; for instance, flight controller 904 may be and/or include a distributed flight controller made up of one or more sub-controllers. For example, and without limitation, sub-controller 940 may include any controllers and/or components thereof that are similar to distributed flight controller and/or flight controller as described above. Sub-controller 940 may include any component of any flight controller as described above. Sub-controller 940 may be implemented in any manner suitable for implementation of a flight controller as described above. As a further non-limiting example, sub-controller 940 may include one or more processors, logic components and/or computing devices capable of receiving, processing, and/or transmitting data across the distributed flight controller as described above. As a further non-limiting example, sub-controller 940 may include a controller that receives a signal from a first flight controller and/or first distributed flight controller component and transmits the signal to a plurality of additional sub-controllers and/or flight components.

Still referring to FIG. 9, flight controller may include a co-controller 944. As used in this disclosure a “co-controller” is a controller and/or component that joins flight controller 904 as components and/or nodes of a distributer flight controller as described above. For example, and without limitation, co-controller 944 may include one or more controllers and/or components that are similar to flight controller 904. As a further non-limiting example, co-controller 944 may include any controller and/or component that joins flight controller 904 to distributer flight controller. As a further non-limiting example, co-controller 944 may include one or more processors, logic components and/or computing devices capable of receiving, processing, and/or transmitting data to and/or from flight controller 904 to distributed flight control system. Co-controller 944 may include any component of any flight controller as described above. Co-controller 944 may be implemented in any manner suitable for implementation of a flight controller as described above.

In an embodiment, and with continued reference to FIG. 9, flight controller 904 may be designed and/or configured to perform any method, method step, or sequence of method steps in any embodiment described in this disclosure, in any order and with any degree of repetition. For instance, flight controller 904 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Flight controller may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

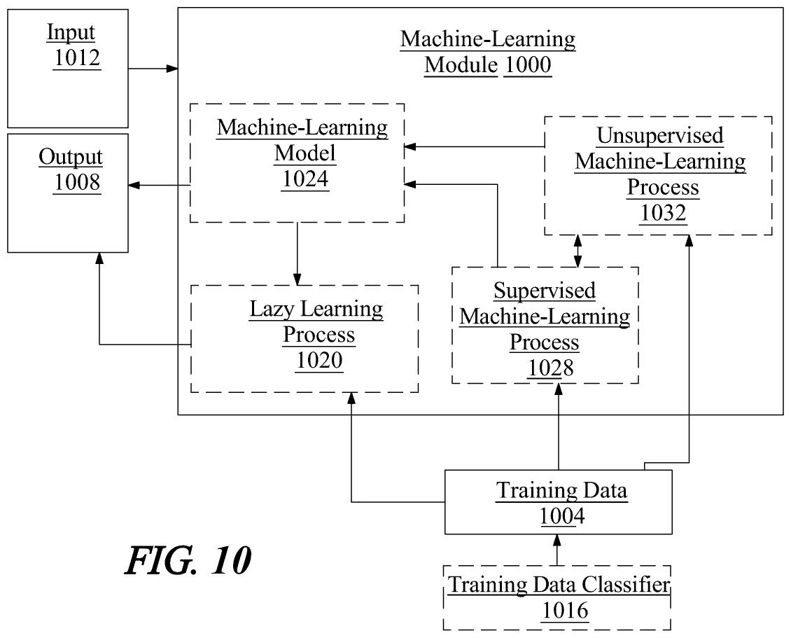

Referring now to FIG. 10, an exemplary embodiment of a machine-learning module 1000 that may perform one or more machine-learning processes as described in this disclosure is illustrated. Machine-learning module may perform determinations, classification, and/or analysis steps, methods, processes, or the like as described in this disclosure using machine learning processes. A “machine learning process,” as used in this disclosure, is a process that automatedly uses training data 1004 to generate an algorithm that will be performed by a computing device/module to produce outputs 1008 given data provided as inputs 1012; this is in contrast to a non-machine learning software program where the commands to be executed are determined in advance by a user and written in a programming language.

Still referring to FIG. 10, “training data,” as used herein, is data containing correlations that a machine-learning process may use to model relationships between two or more categories of data elements. For instance, and without limitation, training data 1004 may include a plurality of data entries, each entry representing a set of data elements that were recorded, received, and/or generated together; data elements may be correlated by shared existence in a given data entry, by proximity in a given data entry, or the like. Multiple data entries in training data 1004 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 1004 according to various correlations; correlations may indicate causative and/or predictive links between categories of data elements, which may be modeled as relationships such as mathematical relationships by machine-learning processes as described in further detail below. Training data 1004 may be formatted and/or organized by categories of data elements, for instance by associating data elements with one or more descriptors corresponding to categories of data elements. As a non-limiting example, training data 1004 may include data entered in standardized forms by persons or processes, such that entry of a given data element in a given field in a form may be mapped to one or more descriptors of categories. Elements in training data 1004 may be linked to descriptors of categories by tags, tokens, or other data elements; for instance, and without limitation, training data 1004 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 10, training data 1004 may include one or more elements that are not categorized; that is, training data 1004 may not be formatted or contain descriptors for some elements of data. Machine-learning algorithms and/or other processes may sort training data 1004 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 1004 to be made applicable for two or more distinct machine-learning algorithms as described in further detail below. Training data 1004 used by machine-learning module 1000 may correlate any input data as described in this disclosure to any output data as described in this disclosure.

Further referring to FIG. 10, training data may be filtered, sorted, and/or selected using one or more supervised and/or unsupervised machine-learning processes and/or models as described in further detail below; such models may include without limitation a training data classifier 1016. Training data classifier 1016 may include a “classifier,” which as used in this disclosure is a machine-learning model as defined below, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Machine-learning module 1000 may generate a classifier using a classification algorithm, defined as a processes whereby a computing device and/or any module and/or component operating thereon derives a classifier from training data 1004. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 1016 may classify elements of training data to data transmission pathways.

Still referring to FIG. 10, machine-learning module 1000 may be configured to perform a lazy-learning process 1020 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 1004. Heuristic may include selecting some number of highest-ranking associations and/or training data 1004 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 10, machine-learning processes as described in this disclosure may be used to generate machine-learning models 1024. A “machine-learning model,” as used in this disclosure, is a mathematical and/or algorithmic representation of a relationship between inputs and outputs, as generated using any machine-learning process including without limitation any process as described above, and stored in memory; an input is submitted to a machine-learning model 1024 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 1024 may be generated by creating an artificial neural network, such as a convolutional neural network comprising an input layer of nodes, one or more intermediate layers, and an output layer of nodes. Connections between nodes may be created via the process of “training” the network, in which elements from a training data 1004 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 10, machine-learning algorithms may include at least a supervised machine-learning process 1028. At least a supervised machine-learning process 1028, as defined herein, include algorithms that receive a training set relating a number of inputs to a number of outputs, and seek to find one or more mathematical relations relating inputs to outputs, where each of the one or more mathematical relations is optimal according to some criterion specified to the algorithm using some scoring function. For instance, a supervised learning algorithm may include node connections as described above as inputs, data transmission pathways as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 1004. Persons skilled in the art, upon reviewing the entirety of this disclosure, will be aware of various possible variations of at least a supervised machine-learning process 1028 that may be used to determine relation between inputs and outputs. Supervised machine-learning processes may include classification algorithms as defined above.

Further referring to FIG. 10, machine learning processes may include at least an unsupervised machine-learning processes 1032. An unsupervised machine-learning process, as used herein, is a process that derives inferences in datasets without regard to labels; as a result, an unsupervised machine-learning process may be free to discover any structure, relationship, and/or correlation provided in the data. Unsupervised processes may not require a response variable; unsupervised processes may be used to find interesting patterns and/or inferences between variables, to determine a degree of correlation between two or more variables, or the like.

Still referring to FIG. 10, machine-learning module 1000 may be designed and configured to create a machine-learning model 1024 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 10, machine-learning algorithms may include, without limitation, linear discriminant analysis. Machine-learning algorithm may include quadratic discriminate analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include various forms of latent space regularization such as variational regularization. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized tress, AdaBoost, gradient tree boosting, and/or voting classifier methods. Machine-learning algorithms may include neural net algorithms, including convolutional neural net processes.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

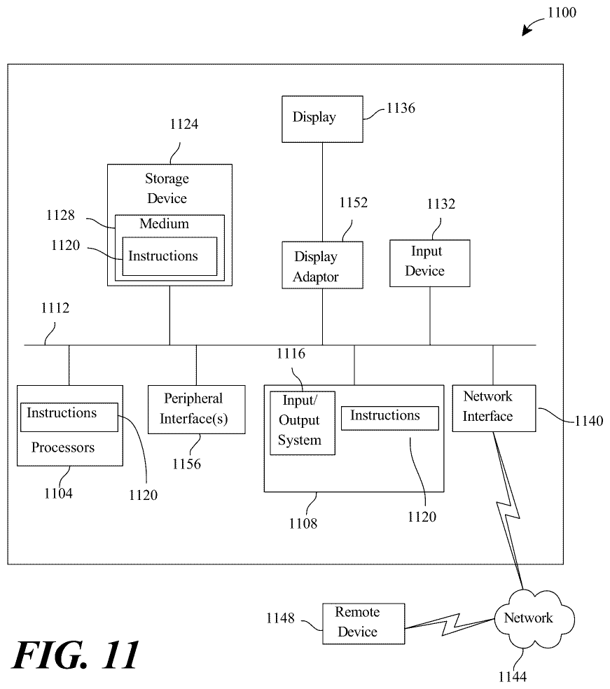

FIG. 11 shows a diagrammatic representation of one embodiment of a computing device in the exemplary form of a computer system 1100 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 1100 includes a processor 1104 and a memory 1108 that communicate with each other, and with other components, via a bus 1112. Bus 1112 may include any of several types of bus structures including, but not limited to, a memory bus, a memory controller, a peripheral bus, a local bus, and any combinations thereof, using any of a variety of bus architectures.

Memory 1108 may include various components (e.g., machine-readable media) including, but not limited to, a random-access memory component, a read only component, and any combinations thereof. In one example, a basic input/output system 1116 (BIOS), including basic routines that help to transfer information between elements within computer system 1100, such as during start-up, may be stored in memory 1108. Memory 1108 may also include (e.g., stored on one or more machine-readable media) instructions (e.g., software) 1120 embodying any one or more of the aspects and/or methodologies of the present disclosure. In another example, memory 1108 may further include any number of program modules including, but not limited to, an operating system, one or more application programs, other program modules, program data, and any combinations thereof.

Computer system 1100 may also include a storage device 1124. Examples of a storage device (e.g., storage device 1124) include, but are not limited to, a hard disk drive, a magnetic disk drive, an optical disc drive in combination with an optical medium, a solid-state memory device, and any combinations thereof. Storage device 1124 may be connected to bus 1112 by an appropriate interface (not shown). Example interfaces include, but are not limited to, SCSI, advanced technology attachment (ATA), serial ATA, universal serial bus (USB), IEEE 894 (FIREWIRE), and any combinations thereof. In one example, storage device 1124 (or one or more components thereof) may be removably interfaced with computer system 1100 (e.g., via an external port connector (not shown)). Particularly, storage device 1124 and an associated machine-readable medium 1128 may provide nonvolatile and/or volatile storage of machine-readable instructions, data structures, program modules, and/or other data for computer system 1100. In one example, software 1120 may reside, completely or partially, within machine-readable medium 1128. In another example, software 1120 may reside, completely or partially, within processor 1104.

Computer system 1100 may also include an input device 1132. In one example, a user of computer system 1100 may enter commands and/or other information into computer system 1100 via input device 1132. Examples of an input device 1132 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 1132 may be interfaced to bus 1112 via any of a variety of interfaces (not shown) including, but not limited to, a serial interface, a parallel interface, a game port, a USB interface, a FIREWIRE interface, a direct interface to bus 1112, and any combinations thereof. Input device 1132 may include a touch screen interface that may be a part of or separate from display 1136, discussed further below. Input device 1132 may be utilized as a user selection device for selecting one or more graphical representations in a graphical interface as described above.

A user may also input commands and/or other information to computer system 1100 via storage device 1124 (e.g., a removable disk drive, a flash drive, etc.) and/or network interface device 1140. A network interface device, such as network interface device 1140, may be utilized for connecting computer system 1100 to one or more of a variety of networks, such as network 1144, and one or more remote devices 1148 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 1144, may employ a wired and/or a wireless mode of communication. In general, any network topology may be used. Information (e.g., data, software 1120, etc.) may be communicated to and/or from computer system 1100 via network interface device 1140.

Computer system 1100 may further include a video display adapter 1152 for communicating a displayable image to a display device, such as display device 1136. Examples of a display device include, but are not limited to, a liquid crystal display (LCD), a cathode ray tube (CRT), a plasma display, a light emitting diode (LED) display, and any combinations thereof. Display adapter 1152 and display device 1136 may be utilized in combination with processor 1104 to provide graphical representations of aspects of the present disclosure. In addition to a display device, computer system. 1100 may include one or more other peripheral output devices including, but not limited to, an audio speaker, a printer, and any combinations thereof. Such peripheral output devices may be connected to bus 1112 via a peripheral interface 1156. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve embodiments according to this disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A system for providing battery performance analytics, the system comprising:
at least one processor; and
at least one memory communicatively connected to the at least one processor, the memory containing instructions configuring the at least one processor to:
retrieve measurement data from a fleet of electric aircrafts over a network, wherein the measurement data includes battery pack parameters and sensor readings from each electric aircraft in the fleet of electric aircrafts;
compiling the measurement data from the fleet of electric aircrafts into a set of fleet data;
train a battery model capable of providing fleet wide battery performance analytics based on the measurement data contained within the fleet data;
collect, via the network, first aircraft measurement data from a memory component in a first aircraft of the fleet of electric aircrafts in response to a detected data connection between the first aircraft and a charging connector during a charging operation at a charging station, wherein the detected data connection also establishes a data connection between the first aircraft and the charging station, and wherein the first aircraft measurement data is periodically stored in the memory component during a flight and is transmitted to the network from the charging station via the data connection between the first aircraft and the charging station;
determine, during the charging operation for the first aircraft, performance analytics of the first aircraft, using the first aircraft measurement data and the battery model; and
initiate, during the charging operation, an alert as a function of the performance analytics of the first aircraft when the performance analytics of the first aircraft are outside of a recommended range.

2. The system of claim 1, wherein the first aircraft measurement data from the first aircraft is obtained from a battery management component attached to a battery pack.

3. The system of claim 2, wherein the battery management component comprises a thermistor configured to detect a temperature of the battery pack.

4. The system of claim 1, wherein the measurement data from the fleet of electric aircrafts includes pilot data associated with aircraft operations by a pilot, wherein the pilot data includes pitch, roll and yaw inputs.

5. The system of claim 1, wherein the performance analytics of the first aircraft comprise an anode health and a cathode health.

6. The system of claim 1, wherein the performance analytics of the first aircraft comprise a recommended surface temperature of a battery pack.

7. The system of claim 1, wherein the memory contains instructions further configuring the at least one processor to transmit the measurement data from the fleet of electric aircrafts to a cloud database communicatively connected to the at least one processor using a communicative connection.

8. The system of claim 1, wherein the measurement data from the fleet of electric aircrafts comprises a voltage of a battery pack.

9. The system of claim 1, wherein the measurement data from the fleet of electric aircrafts comprises a standard discharge capacity.

10. The system of claim 1, wherein the measurement data from the fleet of electric aircrafts comprises a user input using a graphical user interface.

11. The system of claim 1, wherein the at least one processor is further configured to generate a look-up table using the battery model, wherein the look-up table is configured to output performance analytics based on the first aircraft measurement data.

12. A method for providing fleet wide battery performance analytics for a fleet of electric aircrafts, the method comprising:
retrieving, by the at least one processor, measurement data from a fleet of electric aircrafts over a network, wherein the measurement data includes battery pack parameters and sensor readings from each aircraft in the fleet of electric aircrafts;
compiling the measurement data from the plurality of electric aircrafts into a set of fleet data;
training a battery model capable of providing fleet wide battery performance analytics using the measurement data contained in the fleet data;
collecting, via the network, first aircraft measurement data from a memory component of a first aircraft of the fleet of electric aircrafts in response to a detected data connection between the first aircraft and a charging connector during a charging operation at a charging station, wherein the detected data connection also establishes a data connection between the first aircraft and the charging station, and wherein the first aircraft measurement data is periodically stored in the memory component during a flight and is transmitted to the network from the charging station via the data connection between the first aircraft and the charging station;
determining, by the at least one processor during the charging operation for the first aircraft, performance analytics of the first aircraft, using the first aircraft measurement data and the battery model; and
initiating, by the at least one processor during the charging operation, an alert as a function of the performance analytics of the first aircraft when the performance analytics of the first aircraft are outside of a recommended range.

13. The method of claim 12, wherein the first aircraft measurement data from the first aircraft is obtained from a battery management component attached to a battery pack.

14. The method of claim 13, wherein the battery management component comprises a thermistor configured to detect a temperature of the battery pack.

15. The method of claim 12, wherein the measurement data from the fleet of electric aircrafts includes pilot data associated with aircraft operations by a pilot, wherein the pilot data includes pitch, roll and yaw inputs.

16. The method of claim 12, wherein the performance analytics of the first aircraft comprise an anode health and a cathode health.

17. The method of claim 12, further comprising transmitting, by the processor, the measurement data from the fleet of electric aircrafts to a cloud database communicatively connected to the at least one processor.

18. The method of claim 12, wherein the measurement data comprises a voltage of a battery pack.

19. (canceled)

20. (canceled)

21. A system, comprising:
a plurality of electric aircraft, each having an on-board computing system configured to collect measurement data that includes battery pack parameters and sensor readings; and
a remote computing device configured to receive the measurement data from the plurality of electric aircraft over a network, wherein the remote computing device includes a battery model trained using the measurement data from the plurality of electric aircraft, wherein the battery model is configured to:
provide aggregated battery performance analytics applicable to each of the plurality of electric aircraft; and
provide aircraft-specific performance analytics for a first aircraft of the plurality of electric aircraft according to a set of measurement data obtained from the first aircraft; and
a charging station configured to charge the plurality of electric aircraft, wherein in response to a detected charging operation of the first electric aircraft, the detected charging operation establishes a data connection between the first electric aircraft and the charging station, and wherein the remote computing device is further configured to:
receive measurement data from the first electric aircraft over the network, wherein the measurement data is periodically stored in a memory component of the first electric aircraft during a flight and is transmitted to the network from the charging station via the data connection between the first electric aircraft and the charging station;
calculate, at the remote computing device, performance analytics using the trained battery model and the received measurement data from the first electric aircraft; and
forward, during the charging operation, the calculated performance analytics to the first electric aircraft over the network.

22. (canceled)
